(19) United States
(12) Patent Application Publication
(10) Pub. No.: US 2026/0059965 A1
(43) Pub. Date: Feb. 26, 2026

(54) ORGANIC LIGHT EMITTING APPARATUS

(71) Applicant: CANON KABUSHIKI KAISHA, Tokyo (JP)

(72) Inventors: EISUKE GOMMORI, Kanagawa (JP); TETSUO TAKAHASHI, Kanagawa (JP); TAKAYUKI ITO, Kanagawa (JP)

(21) Appl. No.: 19/306,838

(22) Filed: Aug. 21, 2025

(30) Foreign Application Priority Data
Aug. 23, 2024 (JP) 2024-143434

(51) Int. Cl. H10K 59/00; H10K 101/40

(52) U.S. Cl. CPC H10K 59/771; H10K 2101/40

(57) ABSTRACT

An organic light emitting apparatus includes light emitting elements arranged adjacent to each other on a surface of a substrate, each of the light emitting elements having a lower electrode, a charge transport layer, a light emitting layer, and an upper electrode. An insulating layer having an opening on the lower electrode is disposed between the adjacent lower electrodes. At least one of the charge transport layer or the light emitting layer is overlapped with a flat portion of the insulating layer in a plan view. In the plan view, an area of the light emitting layer is larger than an area of the charge transport layer.

### BACKGROUND

### Field of the Technology

The present disclosure relates to an organic light emitting apparatus.

### Description of the Related Art

An organic light emitting element includes an upper electrode, a lower electrode, and an organic layer disposed between the upper electrode and the lower electrode. A charge transport layer included in the organic layer transports charges and produces light by exciting an organic compound contained in a light emitting layer. An example of an apparatus using a light emitting element is a light emitting apparatus, such as a display apparatus that has a plurality of light emitting elements.

For a display apparatus that has organic light emitting elements, a common film formation and color filter method and an independent film formation method are used. The common film formation and color filter method is a method in which an organic layer that produces white light is uniformly formed across pixels to create the pixels with light emitting elements and a color filter is used to separate colors. The independent film formation method is a method in which full-color display is achieved by separately forming a material composition to be formed for each of RGB light emitting sub-pixels. Among these, the independent film formation method is more excellent in terms of luminous efficiency.

There are growing needs for high-definition organic light emitting apparatuses. In high-definition organic light emitting apparatuses, because of the small spacing between the light emitting elements that form the sub-pixels, current flowing within the charge transport layer in an inter-sub-pixel direction cannot be ignored, so a decrease in the luminous efficiency of a pixel portion is a drawback due to, for example, light emission on an insulating layer between the sub-pixels. Japanese Patent Laid-Open No. 2023-123577 discloses an organic light emitting apparatus using an independent film formation method.

In the organic light emitting apparatus of Japanese Patent Laid-Open No. 2023-123577, light emitting layers are independently formed, while the charge transport layers adjacent to the upper and lower sides of the light emitting layers are formed as common layers.

With the above configuration, a region where the charge transport layer on the lower electrode side and the charge transport layer on the upper electrode side come into contact can arise between the pixels, exciplex emission or the like may occur in that part, and, as a result, the luminous efficiency of the pixel portion decreases.

### SUMMARY

The present disclosure can provide an organic light emitting apparatus that suppresses exciplex emission that occurs by the contact between charge transport layers on the upper and lower sides of light emitting layers in an independent film formation method, to suppress a decrease in luminous efficiency.

An aspect of the present disclosure provides an organic light emitting apparatus. The organic light emitting apparatus includes a substrate having a surface, a first lower electrode and a second lower electrode disposed adjacent to each other and on the surface of the substrate; an insulating layer disposed on the substrate, the insulating layer separating the first lower electrode and the second lower electrode, the insulating layer having a first opening portion on the first lower electrode, and the insulating layer having a second opening portion on the second lower electrode; a first lower charge transport layer disposed in the first opening portion; a first light emitting layer disposed on the first lower charge transport layer; a second lower charge transport layer disposed in the second opening portion; a second light emitting layer disposed on the second lower charge transport layer; and an upper charge transport layer disposed on the first light emitting layer and the second light emitting layer, wherein in a plan view to the surface, at least one of the first lower charge transport layer, the second lower charge transport layer, the first light emitting layer, or the second light emitting layer is overlapped with a flat portion between the first opening portion and the second opening portion of the insulating layer, in the plan view to the surface, an area of the first light emitting layer is larger than an area of the first lower charge transport layer, in the plan view to the surface, an area of the second light emitting layer is larger than an area of the second lower charge transport layer,

Features of the present disclosure will become apparent from the following description of embodiments with reference to the attached drawings. The following description of embodiments is described by way of example.

### BRIEF DESCRIPTION OF THE DRAWINGS

FIG. 1 is a sectional view that schematically shows the configuration of an organic light emitting apparatus according to an embodiment.

FIG. 2 is a diagram that schematically shows the relationship among light emitting layers, lower charge transport layers, and opening portions of an insulating layer in a plan view to a surface of a substrate of the organic light emitting apparatus of FIG. 1.

FIGS. 3A to 3C are diagrams that schematically show a film formation method for the lower charge transport layers.

FIG. 4 is a sectional view that schematically shows the configuration of an organic light emitting apparatus according to an embodiment.

FIG. 5 is a diagram that schematically shows the relationship among light emitting layers, lower charge transport layers, and opening portions of an insulating layer in a plan view to a surface of a substrate of an organic light emitting apparatus according to an embodiment.

FIG. 6 is a diagram that schematically shows the relationship among light emitting layers, lower charge transport layers, and opening portions of an insulating layer in a plan view to a surface of a substrate of an organic light emitting apparatus according to an embodiment.

FIG. 7 is a sectional view that schematically shows the configuration of an organic light emitting apparatus according to an embodiment.

FIG. 8 is a sectional view that schematically shows the configuration of an organic light emitting apparatus according to an embodiment.

FIG. 9 is a schematic exploded view that shows an example of a display apparatus according to an embodiment.

FIG. 10A is a schematic view that shows an example of an image capturing apparatus according to an embodiment. FIG. 10B is a schematic view that shows an example of an electronic device according to an embodiment.

FIG. 11A is a schematic view that shows an example of a display apparatus according an embodiment. FIG. 11B is a schematic view that shows an example of a foldable display apparatus.

FIG. 12 is a schematic exploded view that shows an example of an illumination apparatus according to an embodiment.

FIG. 13A is a schematic view that shows an example of an automobile equipped with a vehicle lamp according to an embodiment. FIG. 13B is a schematic view that shows an example of an automobile equipped with a vehicle lamp according to an embodiment.

FIG. 14A is a schematic view that shows an example of a wearable device according to an embodiment. FIG. 14B is a schematic view that shows an example of a wearable device according to an embodiment, which is equipped with an image capturing apparatus.

FIG. 15A is a schematic view that shows an example of an image forming apparatus according to an embodiment. FIG. 15B is a schematic view that shows an example of an exposure light source of an image forming apparatus according to an embodiment. FIG. 15C is a schematic view that shows an example of an exposure light source of an image forming apparatus according to an embodiment.

### DESCRIPTION OF THE EMBODIMENTS

Hereinafter, specific embodiments of the organic light emitting apparatus according to the present disclosure will be described with reference to the attached drawings. In the following description and the drawings, like reference signs are assigned to common components over a plurality of the drawings. Therefore, common components will be described with reference to a plurality of drawings, and the description of components with common reference signs will not be repeated as needed.

### First Embodiment

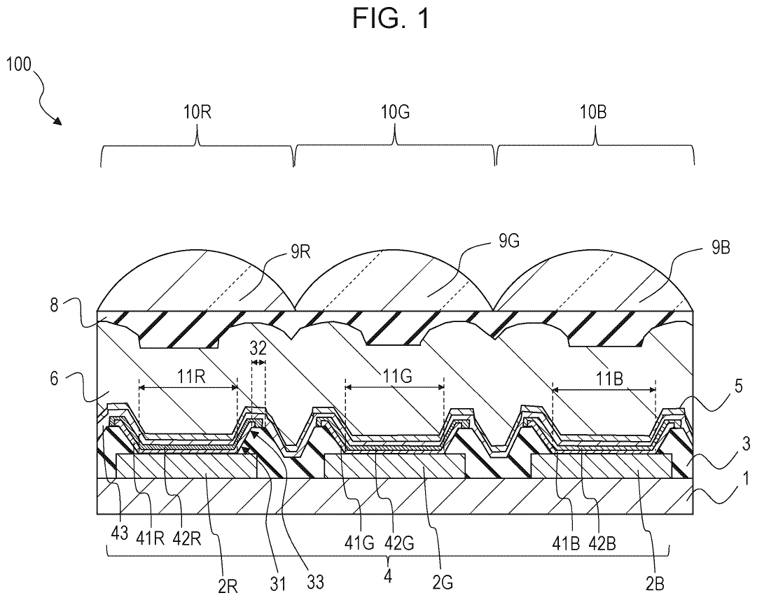

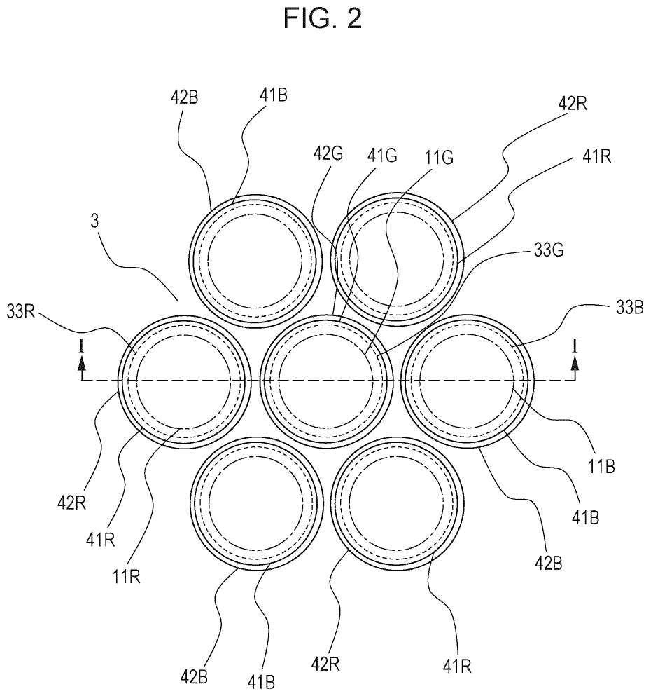

FIG. 1 is a sectional view that schematically shows the configuration of an organic light emitting apparatus according to the first embodiment. FIG. 2 is a diagram that schematically shows the relationship among light emitting layers, lower charge transport layers, and opening portions of an insulating layer in a plan view to a surface of a substrate of the organic light emitting apparatus of FIG. 1. The cross-section taken along the line I-I in FIG. 2 corresponds to the cross-section shown in FIG. 1, and in the present embodiment, one pixel is made up of three light emitting elements (sub-pixels) 10. In the present embodiment, an example of the pixels in a delta array is shown; however, the array is not limited thereto. The array may also be a stripe array or a square array.

In FIGS. 1 and 2, the organic light emitting apparatus of the present embodiment includes a substrate 1, lower electrodes 2, an insulating layer 3, organic layers 4, an upper electrode 5, a protective layer 6, an insulating layer 8 (planarization layer), and microlenses 9. Each of the light emitting elements 10 may include the lower electrode 2, the organic layer 4, and the upper electrode 5. The insulating layer 3 may have opening portions 11 (pixel apertures), inclined portions 31, flat portions 32, and a boundary 33 between each of the inclined portions 31 and a corresponding one of the flat portions 32. Each of the organic layers 4 may have a lower charge transport layer 41, a light emitting layer 42, and an upper charge transport layer 43.

In this specification, “upper” and “lower” refer to the upper and lower sides in FIG. 1. Of the surfaces of the substrate 1, the surface on which the lower electrode 2 and the like are disposed is referred to as “upper” surface. Also, “height” refers to the distance upward from the upper surface (first surface) of the substrate 1. A part parallel to the upper surface (first surface) of the substrate 1 may be designated, and the “height” may be designated based on the designated reference.

The organic light emitting apparatus 100 includes the substrate 1 and the plurality of light emitting elements 10 disposed on the upper surface (first surface) of the substrate 1. FIG. 1 shows three light emitting elements 10R, 10G, and 10B among the plurality of light emitting elements 10 included in the organic light emitting apparatus 100. The “R” in 10R indicates an element that produces red light. Similarly, 10G and 10B indicate to produce green light and blue light, respectively. In the specification, when a specific light emitting element among a plurality of light emitting elements 10 is indicated, a subscript is suffixed to the reference number like light emitting element 10″R″; whereas, a specific light emitting element is not indicated, it is simply indicated as light emitting element “10”. The same applies to the other components.

The plurality of light emitting elements 10 includes, from the upper surface of the substrate 1, the lower electrodes 2 separated for the light emitting elements 10 by the insulating layer 3, the organic layers 4 each including the light emitting layer 42 covering the lower electrode 2 and part of the insulating layer 3, and the upper electrode 5 covering the organic layers 4. The organic light emitting apparatus 100 of the present embodiment is a top emission device that extracts light from the upper electrode 5. Each of the organic layers 4 includes the lower charge transport layer 41 positioned on the lower electrode 2 side of the light emitting layer 42 and the upper charge transport layer 43 positioned on the upper electrode 5 side of the light emitting layer 42, in addition to the light emitting layer 42, as described above. One of the lower charge transport layer 41 and the upper charge transport layer 43 may be a hole transport layer, while the other may be an electron transport layer.

The opening portions (pixel apertures) of the light emitting elements 10R, 10G, 10B are referred to as opening portions 11R, 11G, 11B, respectively. The opening portions here refer to the parts where the insulating layer 3 is not disposed on the lower electrode 2.

Furthermore, the organic light emitting apparatus 100 includes the protective layer 6 disposed so as to cover the upper electrode 5 and the plurality of microlenses 9 disposed on protective layer 6 so as to respectively correspond to the plurality of light emitting elements 10. The organic light emitting apparatus 100 includes the insulating layer (planarization layer) 8 that reduces and planarizes the irregularities of the protective layer 6 between the protective layer 6 and the microlenses 9.

Hereinafter, the description will be sometimes described on the assumption that the lower electrode 2R is a first lower electrode and the lower electrode 2G is a second lower electrode. However, the first lower electrode and the second lower electrode just need to be lower electrodes disposed adjacent to each other and are not limited to the lower electrode 2R and the lower electrode 2G.

As shown in FIG. 1, when it is assumed that the lower electrode 2R is a first lower electrode and the lower electrode 2G is a second lower electrode, the organic light emitting apparatus 100 includes the first lower electrode 2R and the second lower electrode 2G disposed adjacent to each other and on the surface of the substrate 1. The organic light emitting apparatus 100 includes the insulating layer 3 disposed on the substrate 1 and separating the first lower electrode 2R and the second lower electrode 2G. The insulating layer 3 has a first opening portion 11R above the first lower electrode 2R and a second opening portion 11G above the second lower electrode 2G. The organic light emitting apparatus 100 includes a first lower charge transport layer 41R disposed in the first opening portion 11R and a first light emitting layer 42R disposed on the first lower charge transport layer 41R. The organic light emitting apparatus 100 includes a second lower charge transport layer 41G disposed in the second opening portion 11G and a second light emitting layer 42G disposed on the second lower charge transport layer 41G. The organic light emitting apparatus 100 includes the upper charge transport layer 43 disposed on the first light emitting layer 42R and the second light emitting layer 42G. The upper charge transport layer 43 may be disposed on the first light emitting layer 42R, the second light emitting layer 42G, and the insulating layer 3, and may be a common layer disposed continuously on the first light emitting layer 42R and the second light emitting layer 42G.

As shown in FIGS. 1 and 2, in the present embodiment, the light emitting layer 42 and the lower charge transport layer 41 are individually formed for each light emitting element 10. As shown in FIG. 2, in the plan view to the surface of the substrate 1, the area of the light emitting layer 42 (the circular region surrounded by the thick continuous line) is larger than the area of the lower charge transport layer 41 (the circular region surrounded by the thin continuous line). When it is assumed that the lower electrode 2R is a first lower electrode and the lower electrode 2G is a second lower electrode, the area of the first light emitting layer 42R is larger than the area of the first lower charge transport layer 41R, and the area of the second light emitting layer 42G is larger than the area of the second lower charge transport layer 41G, in the plan view to the surface of the substrate 1. As a result, the parts where the upper charge transport layer 43 and the lower charge transport layers 41 come into contact are reduced, so, it is possible to suppress exciplex emission at the contact parts, with the result that it is possible to suppress a decrease in luminous efficiency and deterioration in color purity of the light emitting elements 10.

From the viewpoint of more effectively suppressing exciplex emission, as shown in FIG. 2, the lower charge transport layer 41 can be contained in the light emitting layer 42 in the plan view to the surface of the substrate 1. When it is assumed that the lower electrode 2R is a first lower electrode and the lower electrode 2G is a second lower electrode, the first lower charge transport layer 41R can be contained in the first light emitting layer 42R, and the second lower charge transport layer 41G can be contained in the second light emitting layer 42G in the plan view to the surface of the substrate 1.

From the viewpoint of allowing the opening portion 11 to uniformly produce light, as shown in FIG. 2, the opening portion 11 (the circular region surrounded by the alternate long and short dashed line) can be contained in the lower charge transport layer 41 or contained in the light emitting layer 42 in plan to the surface of the substrate 1. In particular, in the plan view to the surface of the substrate 1, the opening portion 11 can be contained in both the lower charge transport layer 41 and the light emitting layer 42. When it is assumed that the lower electrode 2R is a first lower electrode and the lower electrode 2G is a second lower electrode, the first opening portion 11R can be contained in the first lower charge transport layer 41R or contained in the first light emitting layer 42R in the plan view to the surface of the substrate 1. In addition, in the plan view to the surface of the substrate 1, the second opening portion 11G can be contained in the second lower charge transport layer 41G or contained in the second light emitting layer 42G. In particular, in the plan view to the surface of the substrate 1, the first opening portion 11R can be contained in both the first lower charge transport layer 41R and the first light emitting layer 42R, and the second opening portion 11G can be contained in both the second lower charge transport layer 41G and the second light emitting layer 42G.

The light emitting layers 42 may be light emitting layers individually formed for the light emitting elements 10 or may be a light emitting layer formed as a common layer. When the light emitting layers 42 are formed individually, the lower charge transport layer 41 is formed individually for each light emitting element 10, and, when the light emitting layer 42 is formed as a common layer as well, the parts where the upper charge transport layer 43 and the lower charge transport layers 41 are in contact are reduced, with the result that exciplex emission at the contact parts can be suppressed.

As shown in FIG. 2, in the present embodiment, in the plan view to the surface of the substrate 1, at least one of the lower charge transport layer 41 or the light emitting layer 42, or both, are overlapped with the part between the adjacent opening portions 11 of the insulating layer 3. When it is assumed that the lower electrode 2R is a first lower electrode and the lower electrode 2G is a second lower electrode, at least one of the first lower charge transport layer 41R, the second lower charge transport layer 41G, the first light emitting layer 42R, or the second light emitting layer 42G is overlapped with the part between the first opening portion 11R and second opening portion 11G of the insulating layer 3 in the plan view to the surface of the substrate 1. In particular, in the plan view to the surface of the substrate 1, the first lower charge transport layer 41R and the first light emitting layer 42R, or the second lower charge transport layer 41G and the second light emitting layer 42G can be overlapped with the part between the first opening portion 11R and second opening portion 11G of the insulating layer 3. As shown in FIG. 1, the insulating layer 3 can have the inclined portion 31 that rises from the opening portion 11 and the flat portion 32 that is continuous with the inclined portion 31, and the part between the first opening portion 11R and second opening portion 11G of the insulating layer 3 can be the flat portion 32. In FIG. 2, the boundary 33 between the inclined portion 31 and flat portion 32 of the insulating layer 3 is indicated by the dashed line, and both the lower charge transport layer 41 and the light emitting layer 42 are overlapped with a region outside the boundary 33, that is, the flat portion 32. Here, the flat portion 32 refers to the part where the inclination angle of the upper surface relative to the lower surface of the lower electrode 2 is within ±15°.

When at least one of the lower charge transport layer 41 or the light emitting layer 42 is disposed so as to be overlapped with the part between the adjacent opening portions 11 of the insulating layer 3, the film thickness of the organic layer 4 increases near the opening portions 11 of the insulating layer 3, that is, the inclined portions 31 and the like, so it is possible to reduce leakage current between the upper and lower electrodes. At least one of the lower charge transport layer 41 or the light emitting layer 42 may be disposed so as to be overlapped with the flat portion 32 between the adjacent opening portions 11 of the insulating layer 3. With such a configuration, leakage current between the upper and lower electrodes can be suppressed. As the distance from the part where the lower electrode 2 is in direct contact with the organic layer 4 (light emitting region) increases, the charge that causes leakage current between the upper and lower electrodes or exciplex emission reduces. When at least one of the lower charge transport layer 41 or the light emitting layer 42 is overlapped with the flat portion 32 between the adjacent opening portions 11 of the insulating layer 3, at least one of the lower charge transport layer 41 or the light emitting layer 42 is disposed not only on the opening portions 11 but also on the inclined portions 31 and the flat portions 32. In other words, the region where there is a possibility that the lower charge transport layer 41 and the upper charge transport layer 43 are directly in contact to cause leakage current between the upper and lower electrodes or exciplex emission can be positioned on the flat portion 32, which is far from the light emitting region. Thus, it is possible to suitably suppress the leakage current between the upper and lower electrodes and exciplex emission. At least one of the lower charge transport layer 41 or the light emitting layer 42 extends from the light emitting region to a position to be overlapped with the flat portion 32 between the adjacent opening portions 11 of the insulating layer 3, so a step due to the opening portions 11 can be eased. Thus, it is possible to suppress the disconnection of the upper charge transport layer and upper electrode when disposed as a common layer. Generally, since the light emitting layer 42 has a higher electrical resistance than the lower charge transport layer 41, when the light emitting layer 42 is disposed so as to be overlapped with the part between the adjacent opening portions 11 of the insulating layer 3, it is possible to more effectively suppress the leakage current between the upper and lower electrodes and exciplex emission.

In the organic light emitting element 10, the thin thickness of the organic layer 4 can improve the luminous efficiency. This is because it is possible to reduce light to be absorbed by the organic layer 4. The optical distance L between the pair of electrodes of the organic light emitting element 10 can satisfy the following equation (a). In the organic light emitting element 10, satisfying the following equation (a) means enhancing optical interference between the electrodes, so the organic light emitting element 10 can further improve the luminous efficiency. The luminous efficiency here can also be regarded as extraction efficiency.

$$( λ / 8 ) \times ( - ( 2 φ / π ) - 1 ) < L < ( λ / 8 ) \times ( - ( 2 φ / π ) + 1 ) \qquad ( a )$$

In equation (a), λ is the wavelength of the maximum peak of an emission spectrum produced by the light emitting layer 42 included in the organic layer 4. The maximum peak is a peak at which the intensity is highest among the peaks of the emission spectrum. The peak wavelength may be the shortest wavelength among the peaks included in light emission. φ is a phase shift at the electrode. The phase shift is a phase shift that occurs when light reflects. One of the lower electrode 2 and the upper electrode 5 may be a reflecting electrode, and the other may be an optically transparent electrode. The optically transparent electrode may be an electrode that transmits part of light and reflects another part of the light.

From the viewpoint of suppressing the leakage current between the light emitting elements 10, the carrier mobility can increase as the area reduces, and the carrier mobility can decrease as the area increases, in the plan view to the surface of the substrate 1 in the light emitting element 10. Thus, it is possible to reduce the probability that layers with high carrier mobility are overlapped between pixels, so it is possible to suppress the occurrence of leakage current between pixels. Therefore, it is difficult for current to flow between pixels, so it is possible to suppress exciplex emission between pixels. When it is assumed that the lower electrode 2R is a first lower electrode and the lower electrode 2G is a second lower electrode, the following expression (1) or (2) can be satisfied.

$${H}_{H 1} > {H}_{EM 1} > {E}_{H 3} \qquad ( 1 )$$

H_{H1}: The hole mobility of the first lower charge transport layer 41R
H_{EM1}: The hole mobility of the first light emitting layer 42R
E_{H3}: The electron mobility of the upper charge transport layer 43

$${H}_{H 2} > {H}_{EM 2} > {E}_{H 3} \qquad ( 2 )$$

H_{H2}: The hole mobility of the second lower charge transport layer 41G
H_{EM2}: The hole mobility of the second light emitting layer 42G
E_{H3}: The electron mobility of the upper charge transport layer 43

### Substrate 1

Examples of the substrate 1 include quartz, glass, silicon wafer, resin, and metal. Switching elements, such as transistors, and wires may be provided on the substrate 1, and an insulating layer may be further provided thereon. In FIG. 1, reference sign 1 refers to the substrate, and the substrate 1 may include a drive circuit that includes transistors connected to the lower electrodes 2, and an insulating layer where the drive circuit is disposed. Examples of the insulating layer include an interlayer insulating layer made of inorganic materials, such as silicon oxide and silicon nitride, and organic materials, such as polyimide and polyacrylic. The interlayer insulating layer is sometimes called a planarization layer for the purpose of reducing the irregularities of the surface that forms the lower electrodes 2.

### Lower Electrode 2

A metal material with a reflectance of 80% or more for the emission wavelength of the organic layer 4 may be used for the lower electrode 2. For example, metals, such as Al and Ag, and alloys obtained by adding Si, Cu, Ni, Nd, or the like to these metals may be used for the lower electrode 2. Here, the emission wavelength refers to the spectral range of light emitted from the organic layer 4. When the reflectance of the lower electrode 2 is high for the emission wavelength of the organic layer 4, the lower electrode 2 may have a layered structure that includes a barrier layer. The material of the barrier layer may be a metal, such as Ti, W, Mo, and Au, or an alloy of any of them. The barrier layer may be a metal layer disposed on the upper surface of the lower electrode 2.

### Insulating Layer 3

The insulating layer 3 may cover the end of the lower electrode 2 and may be disposed between the lower electrode 2 and the organic layer 4.

The insulating layer 3 is not limited to the shape as shown in FIG. 1 as long as the insulating layer 3 plays a role in separating the lower electrodes 2 of the light emitting elements 10. The insulating layer 3 may be referred to as a pixel define layer or a bank.

The insulating layer 3 may have the inclined portion 31 at its upper side. The inclined portion 31 rises from the opening portion 11. The upper side can be a side opposite to the substrate 1, or the organic layer side. The flat portion 32 may be provided continuously with the inclined portion 31. The flat portion 32 is a part of which the upper surface is substantially parallel to the lower surface of the lower electrode 2, and is specifically a part of which the inclination of the upper surface relative to the lower surface of the lower electrode 2 is within ±15° in the insulating layer 3.

The insulating layer 3 may be formed by, for example, a chemical vapor deposition method (CVD method) or a physical vapor deposition method (PVD method). The insulating layer 3 may be made of, for example, silicon nitride (SiN), silicon oxynitride (SiON), or silicon oxide (SiO). The insulating layer 3 may be a laminated film of any of them. The inclination angle of the inclined portion 31 of the insulating layer 3 may be controlled by the conditions of anisotropic etching or isotropic etching. The inclination angle of the insulating layer 3 may be controlled by controlling the inclination angle of a layer directly below the insulating layer 3. The insulating layer 3 may have irregularities on its upper surface by, for example, processing using etching or the like, or adding layers.

### Organic Layer 4

The organic layer 4 is disposed between the lower electrode 2 and the upper electrode 5. The organic layer 4 may be made up of the lower charge transport layer 41, the upper charge transport layer 43, and the light emitting layer 42. The upper charge transport layer 43 may be continuously formed over the upper surface of the substrate 1 and shared by the plurality of light emitting elements 10. The lower charge transport layer 41 may be individually formed as the lower charge transport layer 41R for the light emitting element 10R, the lower charge transport layer 41G for the light emitting element 10G, or the lower charge transport layer 41B for the light emitting element 10B. The light emitting layer 42 may be individually formed as the light emitting layer 42R for the light emitting element 10R, the light emitting layer 42G for the light emitting element 10G, or the light emitting layer 42B for the light emitting element 10B. The light emitting layers 42 may have light emitting materials of different light emitting colors. The light emitting layer 42 may have a host material and a dopant material.

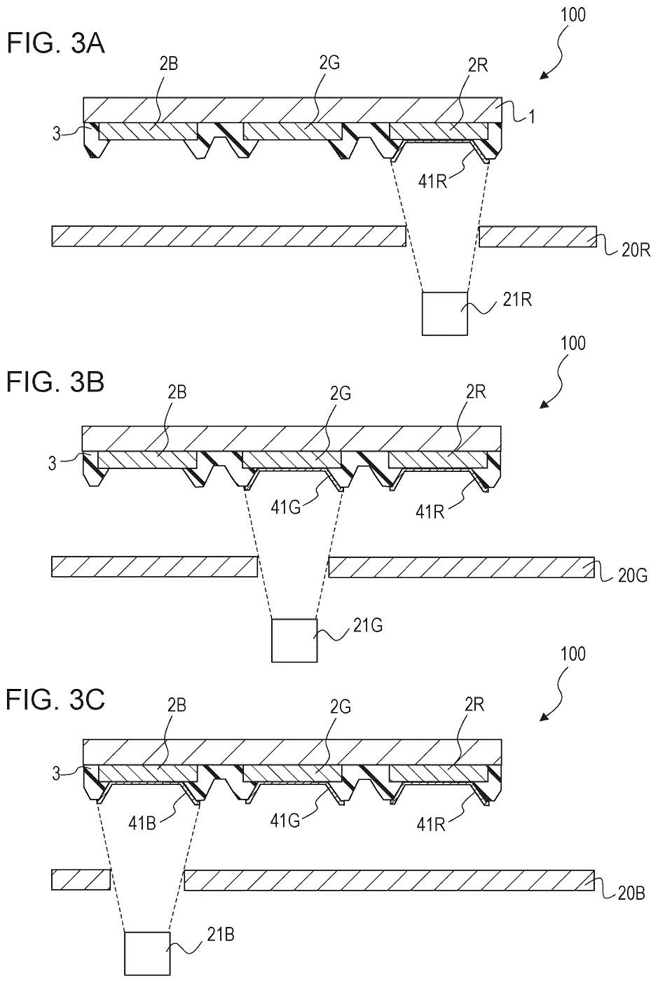

The lower charge transport layer 41 and the light emitting layer 42 may be formed independently using different vapor deposition masks as shown in FIGS. 3A to 3C, or may be formed independently using photolithography. A film formation method for the lower charge transport layers 41R, 41G, 41B of the present embodiment will be described with reference to FIGS. 3A to 3C.

First, the substrate 1, on which the structure of the layers below the insulating layer 3 has been formed, is put into a vapor deposition apparatus. As shown in FIG. 3A, when the lower charge transport layer 41R is formed, a vapor depositing mask 20R with an opening over the lower electrode 2R is used, and heat is applied to a crucible 21R, thus making it possible to form the evaporated organic compound on the lower electrode 2R. Similarly, as shown in FIG. 3B, the lower charge transport layer 41G is formed using a vapor deposition mask 20G and a crucible 21G, and as shown in FIG. 3C, the lower charge transport layer 41B can be formed using a vapor deposition mask 20B and a crucible 21B. As the film formation method of the present embodiment, film formation may be performed by preparing a plurality of crucibles and performing vapor co-deposition.

The organic layer 4 may include a hole transport layer, the light emitting layer 42, and an electron transport layer. The layer disposed between the electrode that becomes an anode out of the upper electrode 5 and the lower electrode 2 and the light emitting layer is the hole transport layer, while the layer disposed between the electrode that becomes a cathode out of the upper electrode 5 and the lower electrode 2 and the light emitting layer is the electron transport layer. The hole transport layer and the electron transport layer are collectively referred to as the charge transport layers.

Appropriate materials are respectively selected for the organic layers 4 from the viewpoint of luminous efficiency, drive life, and optical interference. The hole transport layer may function as an electron block layer or a hole injection layer, and may also have a layered structure of a hole injection layer, a hole transport layer, an electron block layer, and the like. The electron transport layer may function as a hole block layer or an electron injection layer, and may also have a layered structure of an electron injection layer, an electron transport layer, and a hole block layer. Specific materials will be described later.

The organic layer 4 is mainly made of an organic compound; however, the organic layer 4 may include inorganic atoms and inorganic compounds. The organic layer 4 may include, for example, copper, lithium, magnesium, aluminum, iridium, platinum, molybdenum, and zinc. The organic layer 4 may be disposed between the lower electrode 2 and the upper electrode 5 and may be disposed in contact with the lower electrode 2 and the upper electrode 5.

The organic layer 4 can be formed by using a dry process, such as a vacuum evaporation method, an ionized evaporation method, sputtering, and plasma. Instead of the dry process, a wet process in which an organic compound is dissolved in an appropriate solvent and a layer is formed by using a known coating method (such as spin coating, dipping, a casting method, an LB method, and an ink-jet method) may be used. When a layer is formed by using a vacuum evaporation method, a solution coating method, or the like, crystallization or the like is less likely to occur, and it is excellent in temporal stability. When a film is formed by using a coating method, the film can be formed in combination with an appropriate binder resin.

Examples of the binder resin include polyvinyl carbazole resin, polycarbonate resin, polyester resin, ABS resin, acrylic resin, polyimide resin, phenolic resin, epoxy resin, silicon resin, and urea resin; however, the binder resin is not limited to these materials. One type of these binder resins may be used solely as a homopolymer or a copolymer or two or more types of these binder resins may be blended and used. Furthermore, as needed, an additive, such as a known plasticizer, a known oxidation inhibitor, and a known ultraviolet absorbent, may be used together.

### Upper Electrode 5

The upper electrode 5 is disposed on the organic layers 4. The upper electrode 5 is continuously formed on the plurality of light emitting elements 10 and shared by the plurality of light emitting elements 10. The upper electrode 5 may be integrally formed on the entire surface of the display region of the organic light emitting apparatus 100. The display region displays an image. The upper electrode 5 may be an electrode that transmits at least part of light that has reached the lower surface of the upper electrode 5. The upper electrode 5 may function as a transflective layer that transmits part of light while reflecting another part (that is, translucent reflection property). The upper electrode 5 can be formed from a metal, such as magnesium and silver, or an alloy with magnesium or silver as a main component, or an alloy material including an alkali metal or an alkaline earth metal. An oxide conductor or the like may be used for the upper electrode 5. As long as the upper electrode 5 has an appropriate transmittance, the upper electrode 5 may have a layered structure.

### Protective Layer 6

The protective layer 6 may be made of a material having a low permeability of oxygen and moisture from outside, such as silicon nitride, silicon oxynitride, aluminum oxide, silicon oxide, and titanium oxide. The protective layer 6 may be formed of silicon nitride or silicon oxynitride using, for example, a CVD method. On the other hand, the protective layer 6 may be formed of aluminum oxide, silicon oxide, or titanium oxide using an atomic layer deposition method (ALD method). Combinations of the constituent material and manufacturing method for the protective layer 6 are not limited to the above-described illustration, and the protective layer 6 may be manufactured in consideration of the thickness of a layer to be formed, a time needed to form the layer, and the like. The protective layer 6 may have a single-layer structure or a layered structure as long as the protective layer 6 transmits light that has passed through the upper electrode 5 and has a sufficient moisture barrier performance.

### Color Filter 7

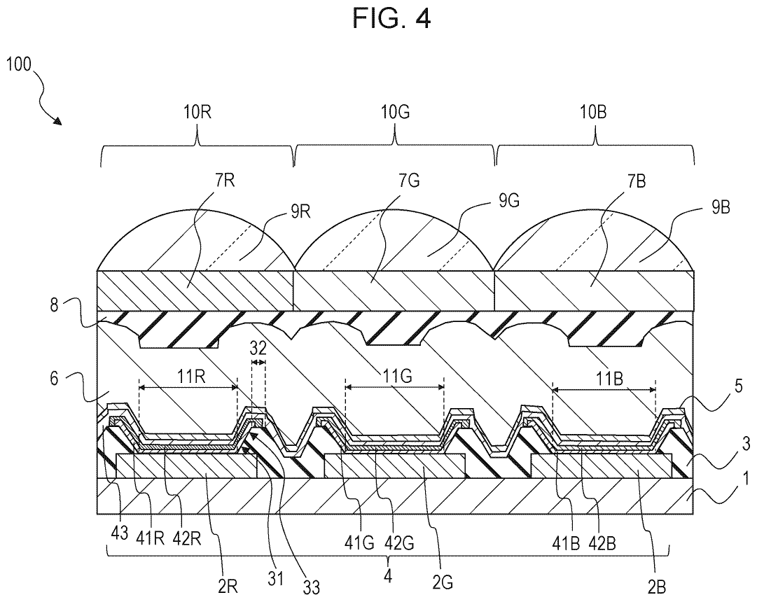

As shown in FIG. 4, color filters 7 may be formed on the protective layer 6. The organic light emitting apparatus 100 shown in FIG. 4 is obtained by further disposing the color filters 7 in the organic light emitting apparatus 100 shown in FIG. 1. The color filters 7 may be in contact with each other without any gaps like the color filter 7R and the color filter 7G shown in FIG. 4. The color filter 7 may be disposed on the color filter 7 of another color so as to be overlapped with the color filter 7. When it is difficult to obtain emission light with a desired wavelength by using only the light emitting element, it is possible to adjust the wavelength with the color filter 7. On the other hand, the organic light emitting apparatus 100 shown in FIG. 1 does not have the color filters 7, and the light emitting layer 42 is disposed independently for each light emitting element 10. With such a configuration, light emitted from the light emitting element 10 is not absorbed by the color filter 7, so it is possible to improve the luminance of light emitted from the organic light emitting apparatus 100.

### Insulating Layer (Planarization Layer) 8

The insulating layer 8 may be provided between the microlenses 9 and the protective layer 6. The insulating layer 8 is provided for the purpose of reducing the irregularities of the lower layer and may be called a planarization layer. The insulating layer 8 may be called a resin material layer without limiting the purpose. The insulating layer 8 may be made of an organic compound and may be a low-molecular compound or a polymer. The insulating layer 8 can be a polymer.

When the organic light emitting apparatus 100 includes the color filters 7, the insulating layer 8 may be provided on both the upper and lower sides of the color filters 7, and the constituent materials of those layers may be the same or may be different. The insulating layer 8 may include any one or some of, for example, polyvinyl carbazole resin, polycarbonate resin, polyester resin, ABS resin, acrylic resin, polyimide resin, phenolic resin, epoxy resin, silicon resin, and urea resin.

### Microlens 9

The organic light emitting apparatus 100 may include an optical member, that is, the microlenses 9 or the like, on its light emission side.

The microlenses 9 can be made of acrylic resin, epoxy resin, or the like. The microlenses 9 may be provided for the purpose of increasing the amount of light extracted from the organic light emitting apparatus 100 and controlling the direction in which light is extracted. Each of the microlenses 9 may have a hemispherical shape. When the microlens 9 has a hemispherical shape, there is a tangent parallel to the insulating layer 8 among tangents that touch the hemisphere, and the contact between the parallel tangent and the hemisphere is the vertex of the microlens 9. The vertex of the microlens 9 can be similarly determined even in a selected sectional view. In other words, there is a tangent parallel to the insulating layer 8 among tangents that touch the semicircle of the microlens 9 in the sectional view, and the contact between the parallel tangent and the semicircle is the vertex of the microlens 9.

The middle point of the microlens 9 may be defined. In the cross section of the microlens 9, a line segment from a point at which the shape of a circular arc ends to another point at which the shape of the circular arc ends is imagined, and the middle point of the line segment can be called the middle point of the microlens 9. A cross section to determine a vertex and a middle point may be a cross section perpendicular to the insulating layer 8.

The microlens 9 has a first surface having a convex portion and a second surface opposite to the first surface. The second surface can be disposed closer to the organic layer 4 than the first surface. To provide such a configuration, the microlenses 9 need to be formed on the organic light emitting apparatus 100. Since the organic layer 4 may decompose at high temperatures, processes that involve high temperatures can be avoided in the manufacturing process for the microlenses 9. When the second surface is disposed closer to the organic layer 4 than the first surface, all the glass transition temperatures of the organic compounds that make up the organic layer 4 are preferably higher than or equal to 100° C. and more preferably higher than or equal to 130° C.

### Counter Substrate

A counter substrate may be provided on the insulating layer 8 (planarization layer). The counter substrate is provided at a position corresponding to the above-described substrate 1, so it is called a counter substrate. The constituent material of the counter substrate may be the same as that of the above-described substrate 1. When the above-described substrate 1 is a first substrate, the counter substrate may be a second substrate.

### Pixel Circuit

The organic light emitting apparatus 100 may include pixel circuits connected to the light emitting elements 10. The pixel circuits may be of an active matrix type and independently control a first light emitting element and a second light emitting element. The active-matrix circuits may operate in accordance with voltage programming or current programming. A drive circuit includes the pixel circuit for each pixel. Each of the pixel circuits may include the light emitting element 10, a transistor that controls the emission luminance of the light emitting element, a transistor that controls light emission timing, a capacitor that holds the gate voltage of the transistor that controls the emission luminance, and a transistor for connection with a GND without intervening the light emitting element 10.

The organic light emitting apparatus 100 may include a display region and a peripheral region disposed around the display region. The display region includes the pixel circuits, and the peripheral region includes a display control circuit. The mobility of the transistor that is a component of the pixel circuit may be smaller than the mobility of a transistor that is a component of the display control circuit.

The slope of the current-voltage characteristics of the transistor that is a component of the pixel circuit may be smaller than the slope of the current-voltage characteristics of the transistor that is a component of the display control circuit. The slope of the current-voltage characteristics can be measured in accordance with so-called Vg-Ig characteristics. The transistor that is a component of the pixel circuit is a transistor connected to the light emitting element 10, such as a first light emitting element.

### Pixel

The organic light emitting apparatus 100 includes the plurality of pixels. Each pixel has sub-pixels that produce light in different colors from each other. The sub-pixels may respectively have, for example, RGB light emitting colors.

The region of the pixel called a pixel aperture produces light. The pixel aperture may be less than or equal to 15 μm and may be greater than or equal to 5 μm. More specifically, the pixel aperture may be 11 μm, 9.5 μm, 7.4 μm, 6.4 μm, or the like. An interval between the sub-pixels may be less than or equal to 10 μm and, specifically, may be 8 μm, 7.4 μm, or 6.4 μm.

The pixels can take a known arrangement mode in a plan view. The pixels may be arranged in, for example, a stripe array, a delta array, a pentile array, or a Bayer array. The shape of each sub-pixel in a plan view may be any one of known shapes. The shape of each sub-pixel in a plan view is, for example, a quadrangular shape, such as a rectangular shape and a rhombic shape, or a hexagonal shape. Of course, when the shape is not an exact shape but is close to a rectangular shape, the shape is assumed to be included in a rectangular shape. The shape of each sub-pixel and the pixel array may be used in combination.

### Second Embodiment

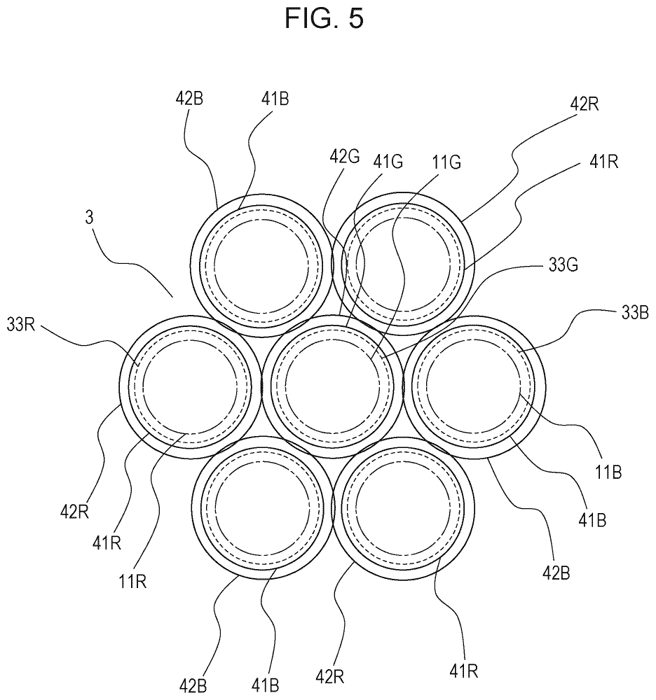

An organic light emitting apparatus according to the second embodiment will be described with reference to FIG. 5. In the following description, the differences from the first embodiment will be mainly described.

FIG. 5 is a diagram that schematically shows the relationship among light emitting layers, lower charge transport layers, and opening portions of an insulating layer in a plan view to a surface of a substrate of the organic light emitting apparatus according to the second embodiment. As shown in FIG. 5, in the plan view to the surface of the substrate 1, the adjacent light emitting layers 42 may have overlapping parts. When it is assumed that the lower electrode 2R is a first lower electrode and the lower electrode 2G is a second lower electrode, the first light emitting layer 42R and the second light emitting layer 42G may have overlapping parts in the plan view to the surface of the substrate 1. In this embodiment as well, the part where the upper charge transport layer 43 and the lower charge transport layer 41 come into contact is reduced, so, it is possible to suppress exciplex emission at the contact part, with the result that it is possible to suppress a decrease in luminous efficiency and deterioration in color purity of the light emitting elements 10.

### Third Embodiment

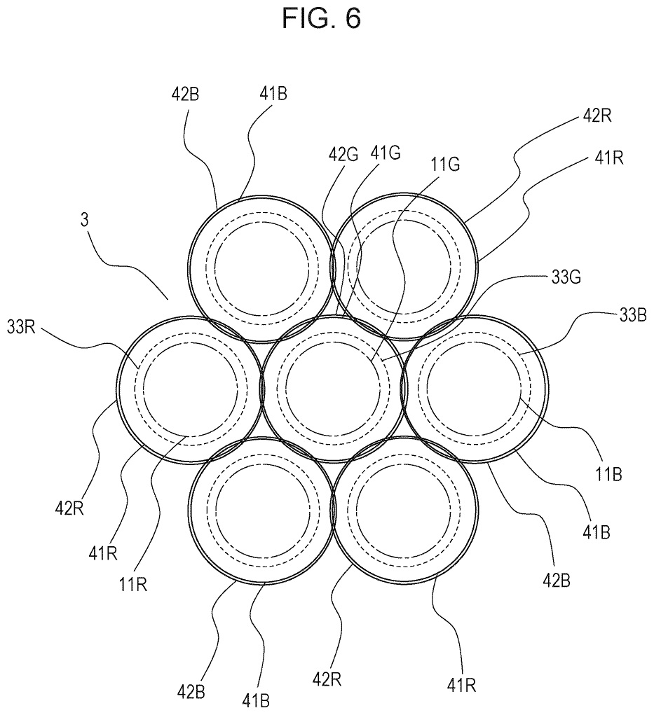

An organic light emitting apparatus according to the third embodiment will be described with reference to FIG. 6. In the following description, the differences from the second embodiment will be mainly described.

FIG. 6 is a diagram that schematically shows the relationship among light emitting layers, lower charge transport layers, and opening portions of an insulating layer in a plan view to a surface of a substrate of the organic light emitting apparatus according to the third embodiment. As shown in FIG. 6, in the plan view to the surface of the substrate 1, not only the adjacent light emitting layers 42 but also the adjacent lower charge transport layers 41 may have overlapping parts. When it is assumed that the lower electrode 2R is a first lower electrode and the lower electrode 2G is a second lower electrode, the first lower charge transport layer 41R and the second lower charge transport layer 41G may have overlapping parts in the plan view to the surface of the substrate 1. In this embodiment as well, the part where the upper charge transport layer 43 and the lower charge transport layer 41 come into contact is reduced, so, it is possible to suppress exciplex emission at the contact part, with the result that it is possible to suppress a decrease in luminous efficiency and deterioration in color purity of the light emitting elements 10.

### Fourth Embodiment

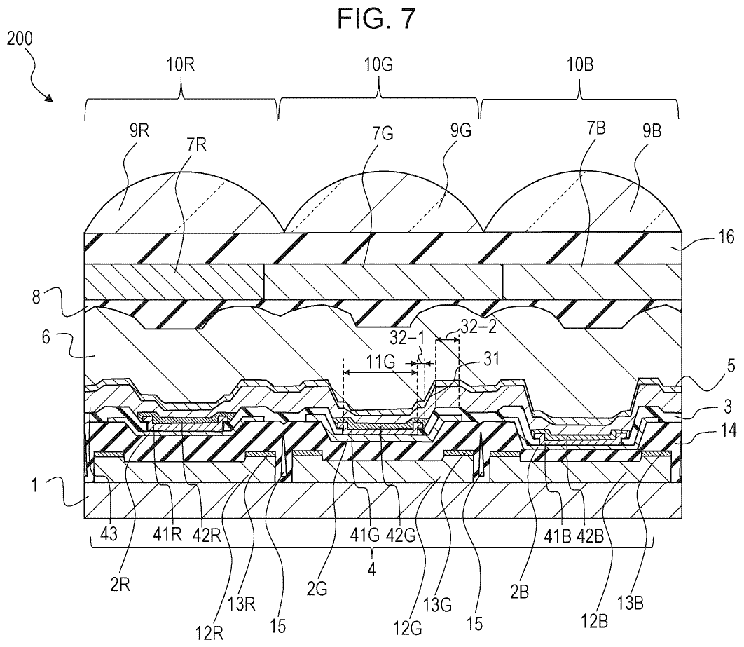

An organic light emitting apparatus according to the fourth embodiment will be described with reference to FIG. 7. In the following description, the differences from the first embodiment will be mainly described.

FIG. 7 is a sectional view that schematically shows the configuration of the organic light emitting apparatus according to the fourth embodiment. The organic light emitting apparatus 200 according to the fourth embodiment includes reflective layers 12, conductive layers 13, an optical adjustment layer 14, and gaps 15 between the substrate 1 and the lower electrodes 2, in addition to the organic light emitting apparatus 100 according to the first embodiment. Furthermore, the organic light emitting apparatus 200 according to the fourth embodiment includes an insulating layer (planarization layer) 16 between the color filters 7 and the microlenses 9, in addition to the organic light emitting apparatus 100 according to the first embodiment.

### Reflective Layer 12

The reflective layer 12 is a layer that reflects light produced by the organic layer 4 and traveling toward the substrate 1. The reflective layer 12 may be separate for each light emitting element 10.

With the configuration shown in FIG. 7, the flat portions of the insulating layer 3 may be present at two or more positions. Specifically, a first flat portion 32-1 located along the periphery of the opening portion 11 and a second flat portion 32-2 continuous with the inclined portion 31 may be provided. As shown in FIG. 7, the lower charge transport layer 41 and the light emitting layer 42 may be disposed so as to be overlapped with only the first flat portion 32-1. The first flat portion 32-1 and the second flat portion 32-2 refer to parts that are substantially parallel to the lower surface of the lower electrode 2 and the angle formed between their upper surfaces and the lower surface of the lower electrode 2 is within ±15°.

For example, the lower charge transport layers 41G, 41B, and the light emitting layers 42G, 42B are disposed in regions that are not overlapped with the second flat portion 32-2. As a result, when, for example, the lower charge transport layer 41R and the light emitting layer 42R are formed using a vapor deposition process, the lower charge transport layers 41G, 41B and the light emitting layers 42G, 42B are not formed on the second flat portions 32-2 that contact with the mask. Therefore, it is possible to suppress the occurrence of foreign substances due to contact between these layers and the mask.

From the viewpoint of the luminous efficiency of the organic light emitting apparatus 200, the reflective layer 12 may be made of a material having a reflectance of visible light of 50% or more. Specifically, a metal, such as Al and Ag, or an alloy made by adding Si, Cu, Ni, Nd, Ti, or the like to those metals may be used as the reflective layer 12. The reflective layer 12 may have a barrier layer on the surface that reflects light. The material of the barrier layer of the reflective layer 12 may be a metal, such as Ti, W, Mo, and Au, or an alloy of those metals, or a transparent conductive oxide, such as ITO and IZO.

### Conductive Layer 13

The conductive layer 13 may be provided along the outer periphery of the reflective layer 12. The conductive layer 13 may be made of, for example, Ti or TiN, and may be the barrier layer. By providing the conductive layer 13 on the reflective layer 12, it is possible to reduce the resistance when the reflective layer 12 and the lower electrode 2 are electrically connected.

### Optical Adjustment Layer 14

The optical adjustment layer 14 is an insulating layer with translucency and is disposed between the reflective layers 12 and the lower electrodes 2. The optical adjustment layer 14 of the organic light emitting apparatus 200 is continuously disposed over the plurality of light emitting elements 10; however, the optical adjustment layer 14 is provided such that the thickness is varied for each light emitting element 10. Thus, a configuration (resonant structure) that optimizes the optical distance between the reflective layer 12 and the light emitting position of the light emitting layer 42 in the organic layer 4 for each color may be provided.

The optical adjustment layer 14 may be made up of a single layer or may be made up of multiple layers. The optical adjustment layer 14 is made up of multiple layers, and the number of laminated layers may vary for each light emitting element 10. The material of the optical adjustment layer 14 is not limited, and, for example, silicon oxide (SiOx) may be used. The optical adjustment layer 14 may have the gaps 15 formed by the steps of the reflective layers 12.

### Lower Electrode 2

The lower electrodes 2 are disposed on the optical adjustment layer 14. As described in the first embodiment, the lower electrode 2 is disposed so as to be electrically separated for each sub-pixel (light emitting element 10). The lower electrodes 2 can be made of a transparent material, for example, an oxide conductor, such as ITO, IZO, ZnO, AZO, and IGZO. Although not shown in the drawing, each lower electrode 2 may extend to the opening (contact hole) provided in the optical adjustment layer 14 and electrically connected to the conductive layer 13 around the reflective layer 12 disposed below the lower electrode 2 at the opening.

### Substrate 1

In FIG. 7, reference sign 1 refers to the substrate, and the substrate 1 may include a drive circuit that includes transistors connected to the reflective layers 12, and an interlayer insulating layer disposed on the drive circuit.

### Insulating Layer (Planarization Layer) 16

An insulating layer 16 may be provided between the color filters 7 and the microlenses 9. The insulating layer 16 is provided for the purpose of reducing the irregularities of the lower layer and may be called a planarization layer. The insulating layer 16 may be called a resin material layer without limiting the purpose. The insulating layer 16 may be made of an organic compound and may be a low-molecular compound or a polymer. The insulating layer 16 can be a polymer.

The insulating layer 16 may be made of the same constituent material as the insulating layer (planarization layer) 8 provided below the color filters 7. Specifically, the planarization layer may be polyvinyl carbazole resin, polycarbonate resin, polyester resin, ABS resin, acrylic resin, polyimide resin, phenolic resin, epoxy resin, silicon resin, urea resin, or the like.

The optical distance between the upper electrode 5 and reflective layer 12 of the organic light emitting apparatus 200 according to the present embodiment may be configured to provide a constructive interference structure. The constructive interference structure can also be referred to as a resonant structure.

When it is assumed that the lower electrode 2R is a first lower electrode and the lower electrode 2G is a second lower electrode, the reflective layers 12 and the optical adjustment layer 14 may be further provided, from the substrate 1 side, between the substrate 1 and both the first lower electrode 2R and the second lower electrode 2G in this way. The thickness of the optical adjustment layer 14 below the first lower electrode 2R and the thickness of the optical adjustment layer 14 below the second lower electrode 2G may have different structures from each other. This structure tends to create a large step between the light emitting elements 10 because the thickness of the optical adjustment layer 14 is varied for each light emitting element 10. Thus, the advantage effects of the present disclosure can be greatly enjoyed.

### Fifth Embodiment

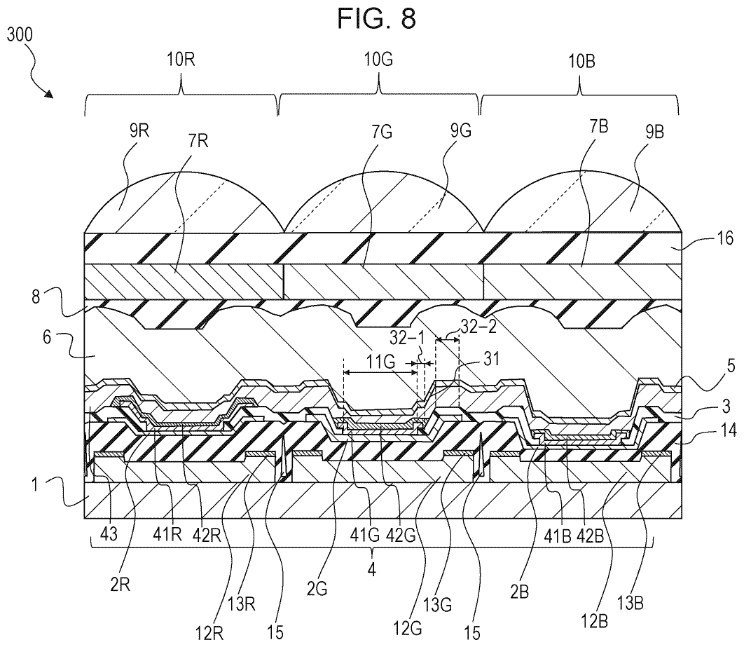

An organic light emitting apparatus according to the fifth embodiment will be described with reference to FIG. 8. In the following description, the differences from the fourth embodiment will be mainly described.

FIG. 8 is a sectional view that schematically shows the configuration of the organic light emitting apparatus according to the fifth embodiment. In FIG. 8, the lower charge transport layer 41R and light emitting layer 42R of the light emitting element 10R are disposed so as to be overlapped with the first flat portion 32-1 and the second flat portion 32-2. Since the region where the lower charge transport layer 41R and the light emitting layer 42R are disposed expands as described above, it is possible to widen the process margin during film formation.

### Material of Organic Layer

As the material for the organic layers 4, generally known low-molecular and polymer hole injection compounds or hole transport compounds, host compounds, light emitting compounds, electron injection compounds, electron transport compounds, or the like, can be used. Here are some examples of these compounds.

Hole injection and transport materials can be materials with high hole mobility, which facilitate the injection of holes from the anode and can transport the injected holes to the light emitting layer. In order to reduce the degradation of film quality, such as crystallization, in the organic light emitting elements, materials with a high glass transition temperature can be used. Low-molecular and polymer materials with hole injection transport capabilities include triarylamine derivatives, aryl carbazole derivatives, phenylenediamine derivatives, stilbene derivatives, phthalocyanine derivatives, porphyrin derivatives, poly(vinyl carbazole), poly(thiophene), and other conductive polymers. Furthermore, the hole injection and transport materials are also suitably used for electron blocking layers. Hereinafter, specific examples of compounds used as hole injection and transport materials will be described; however, of course, the hole injection and transport materials are not limited thereto.

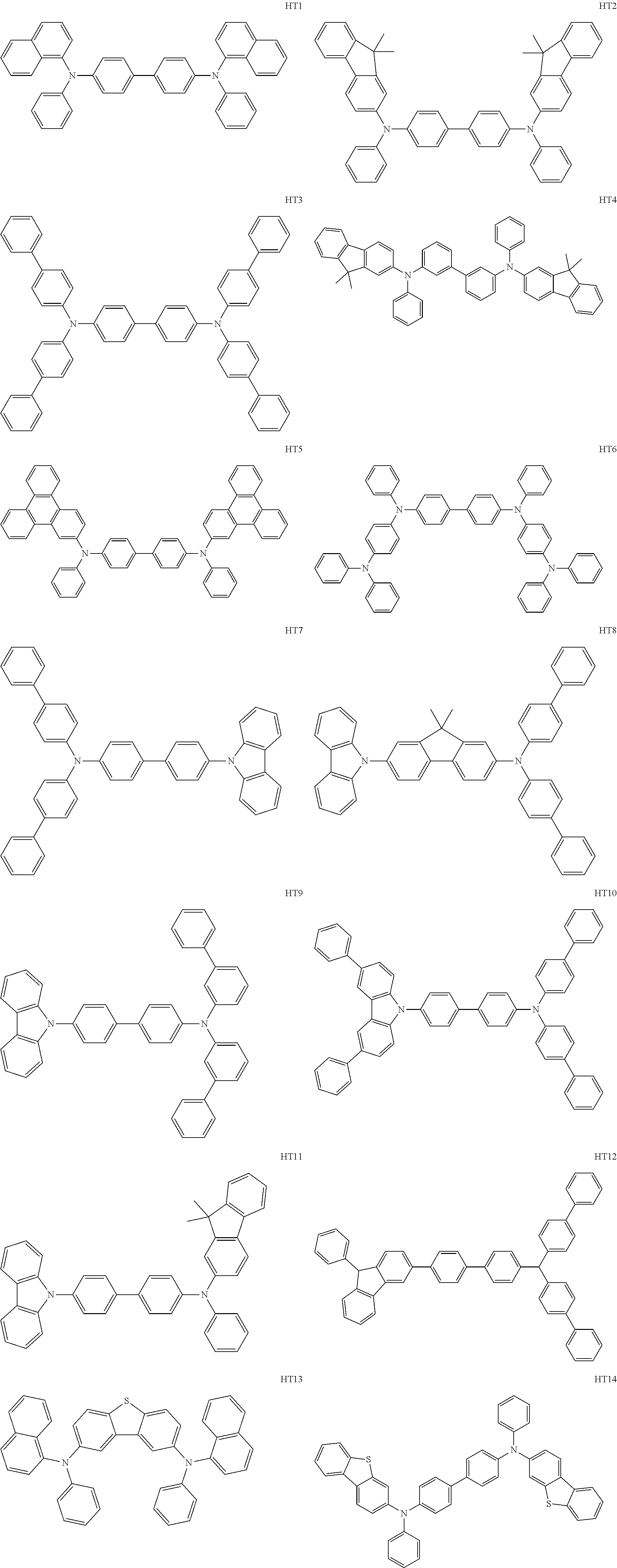

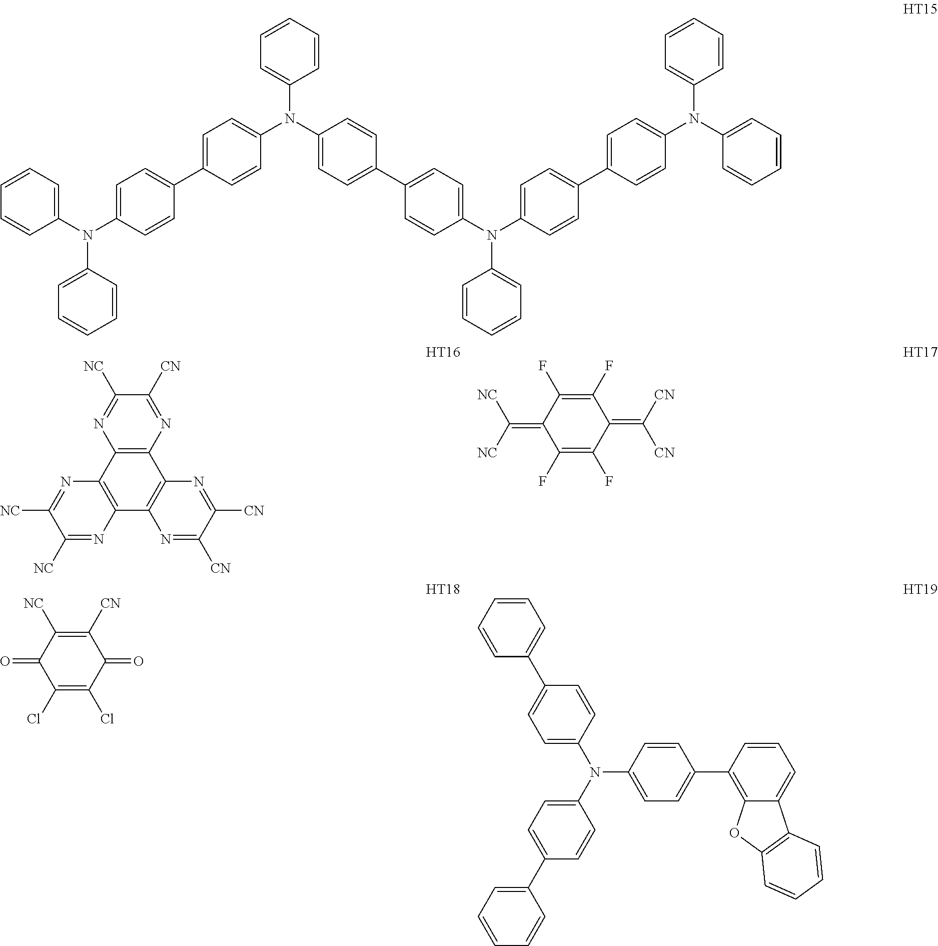

Among the listed hole transport materials, HT16 to HT18 can be used for layers that are in contact with anodes to reduce drive voltage. HT16 is widely used for organic light emitting elements. HT2 to HT6, HT10, and HT12 may be used for organic compound layers adjacent to HT16. A plurality of materials may be used for a single organic compound layer.

Light emitting materials mainly related to light emitting functions include fused ring compounds (such as fluorene derivatives, naphthalene derivatives, pyrene derivatives, perylene derivatives, tetracene derivatives, anthracene derivatives, and rubrene), quinacridone derivatives, coumarin derivatives, stilbene derivatives, organic aluminum complexes such as tris(8-quinolinolato)aluminum, iridium complexes, platinum complexes, rhenium complexes, copper complexes, europium complexes, ruthenium complexes, and polymer derivatives such as poly(phenylene vinylene) derivatives, poly(fluorene) derivatives, and poly(phenylene) derivatives. Hereinafter, specific examples of compounds used as light emitting materials will be described; however, of course, the light emitting materials are not limited thereto.

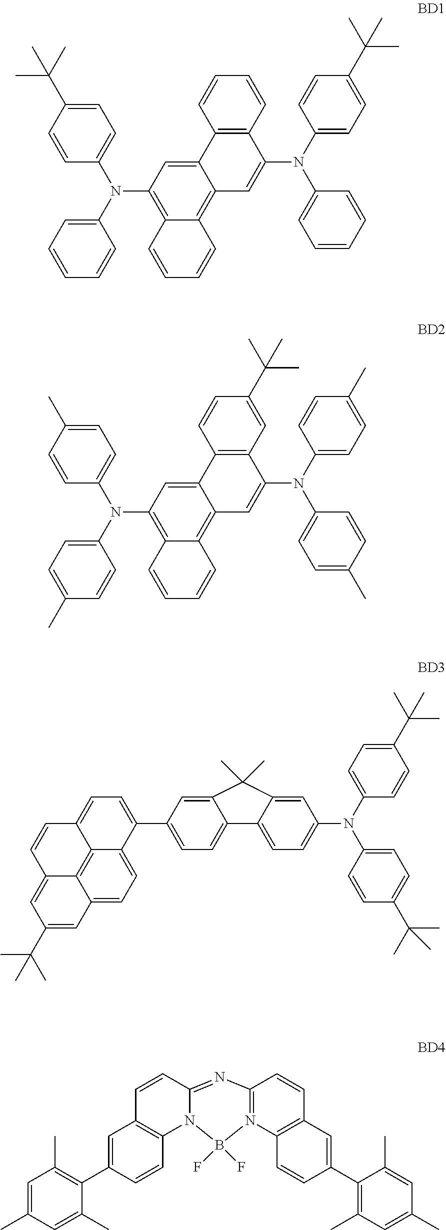

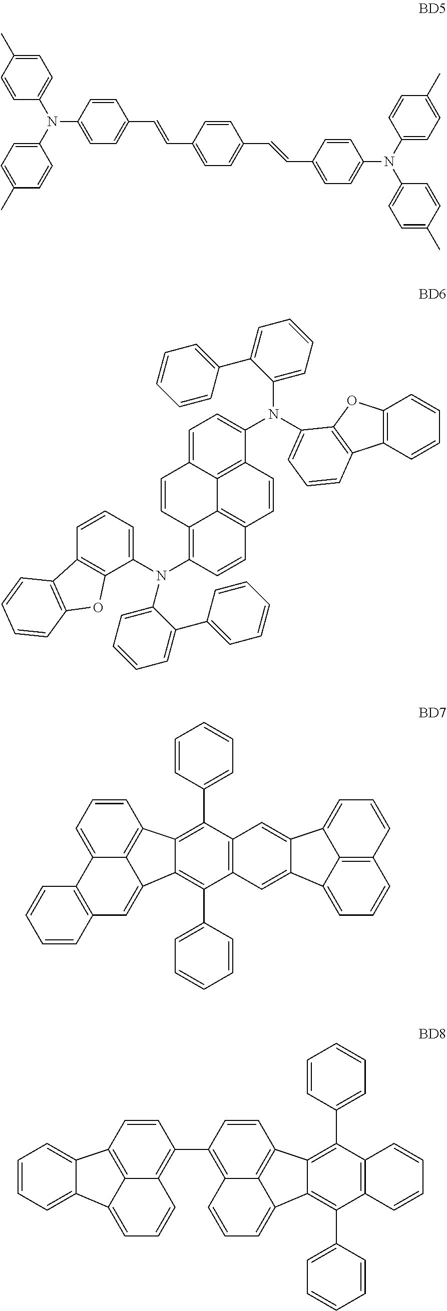

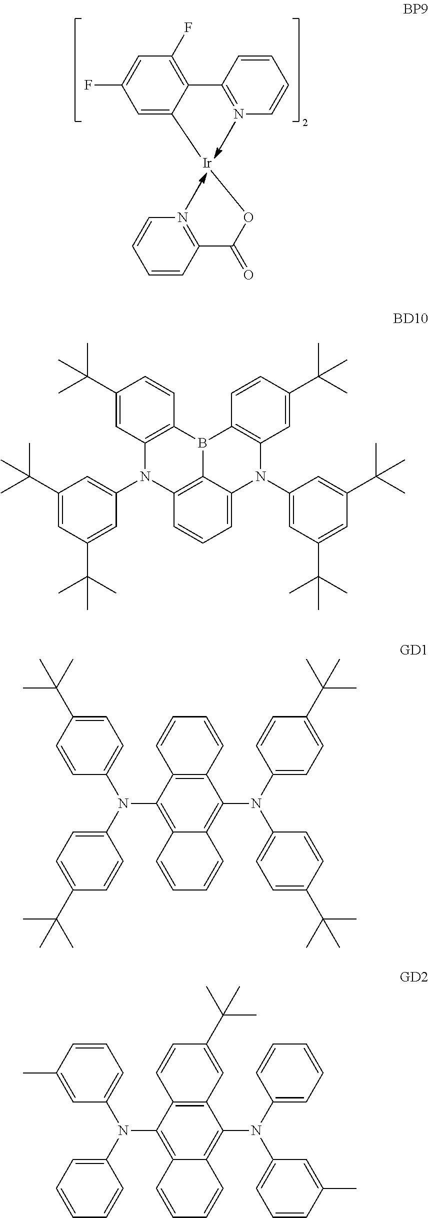

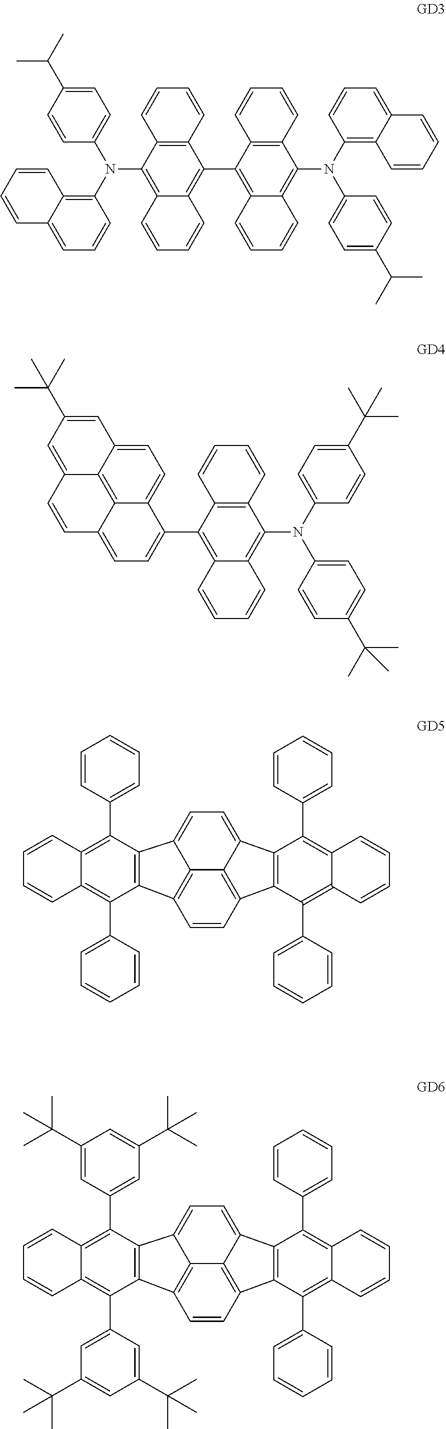

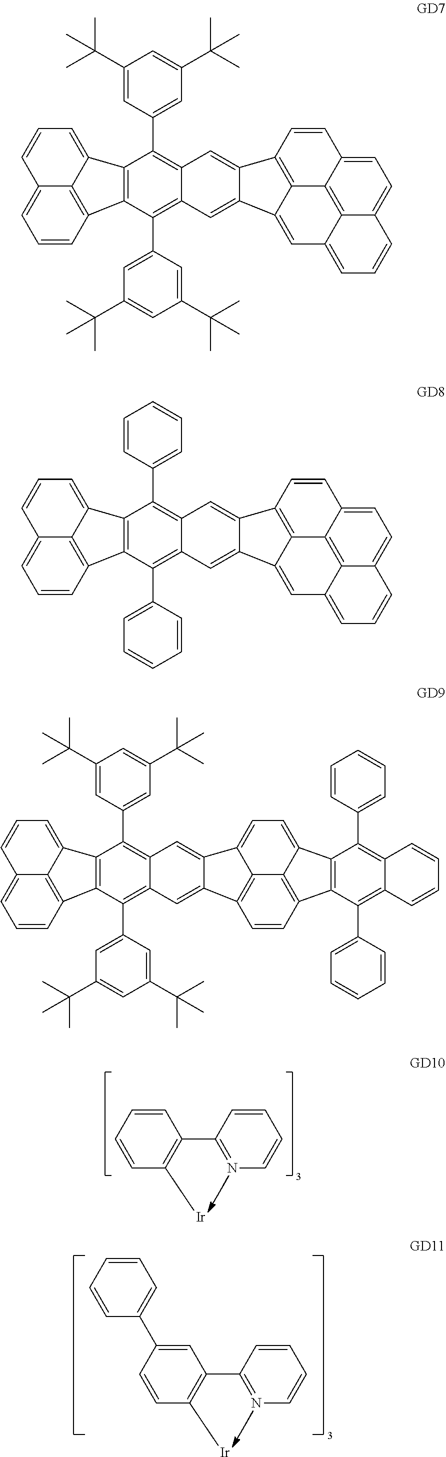

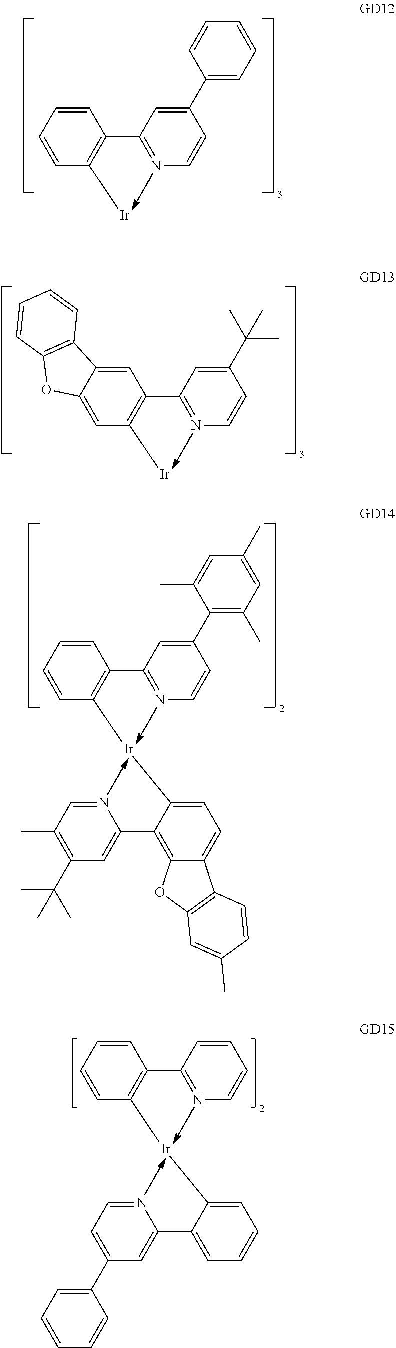

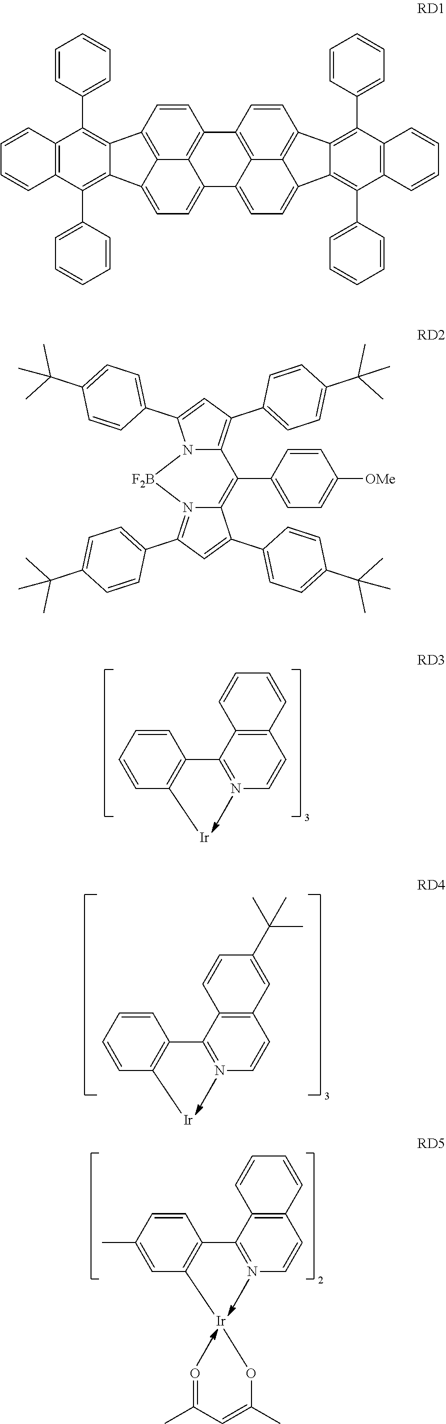

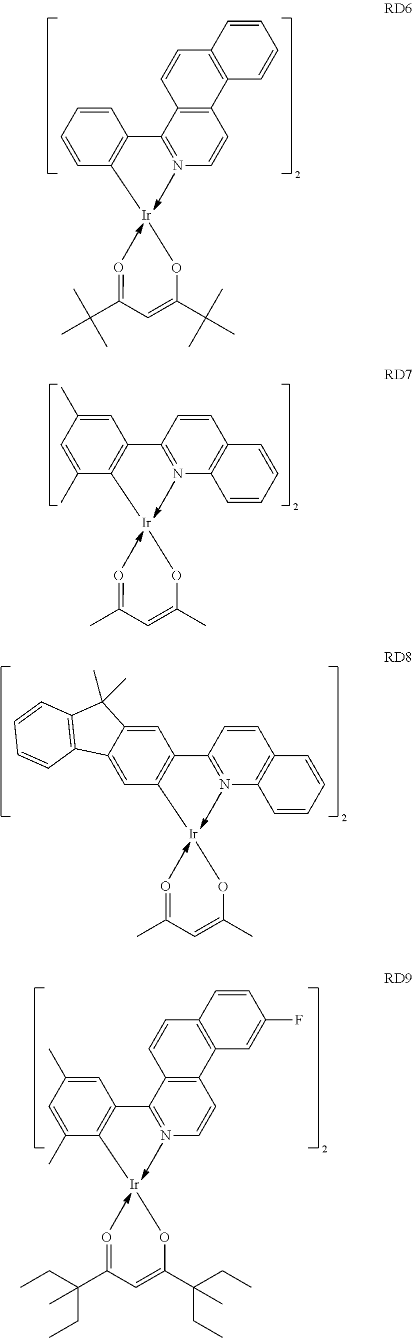

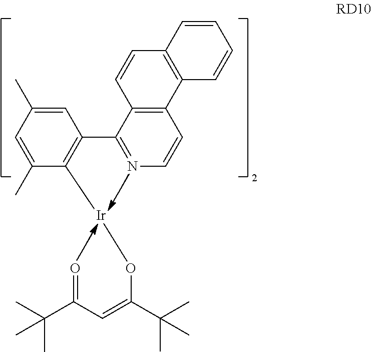

When the light emitting material is a hydrocarbon compound, a decrease in luminous efficiency due to exciplex formation and a decrease in color purity due to changes in the emission spectrum of the light emitting material caused by exciplex formation can be reduced. Hydrocarbon compounds are compounds made of only carbon and hydrogen, and are BD7, BD8, GD5 to GD9, and RD1 among the illustrated compounds.

When the light emitting material is a fused polycyclic compound including a five-membered ring, the light emitting material has a high ionization potential, so the light emitting material can be difficult to oxidize and can result in an element with a highly durable life. The above-described light emitting materials are BD7, BD8, GD5 to GD9, and RD1 among the illustrated compounds.

Examples of light emitting layer hosts or light emission assisting materials contained in the light emitting layers include aromatic hydrocarbon compounds or their derivatives, carbazole derivatives, dibenzofuran derivatives, dibenzothiophene derivatives, organic aluminum complexes, such as tris(8-quinolinolato)aluminum, and organic beryllium complexes. Hereinafter, specific examples of compounds used as light emitting layer hosts or light emission assisting materials contained in the light emitting layers will be described; however, of course, the light emitting layer hosts or light emission assisting materials are not limited thereto.

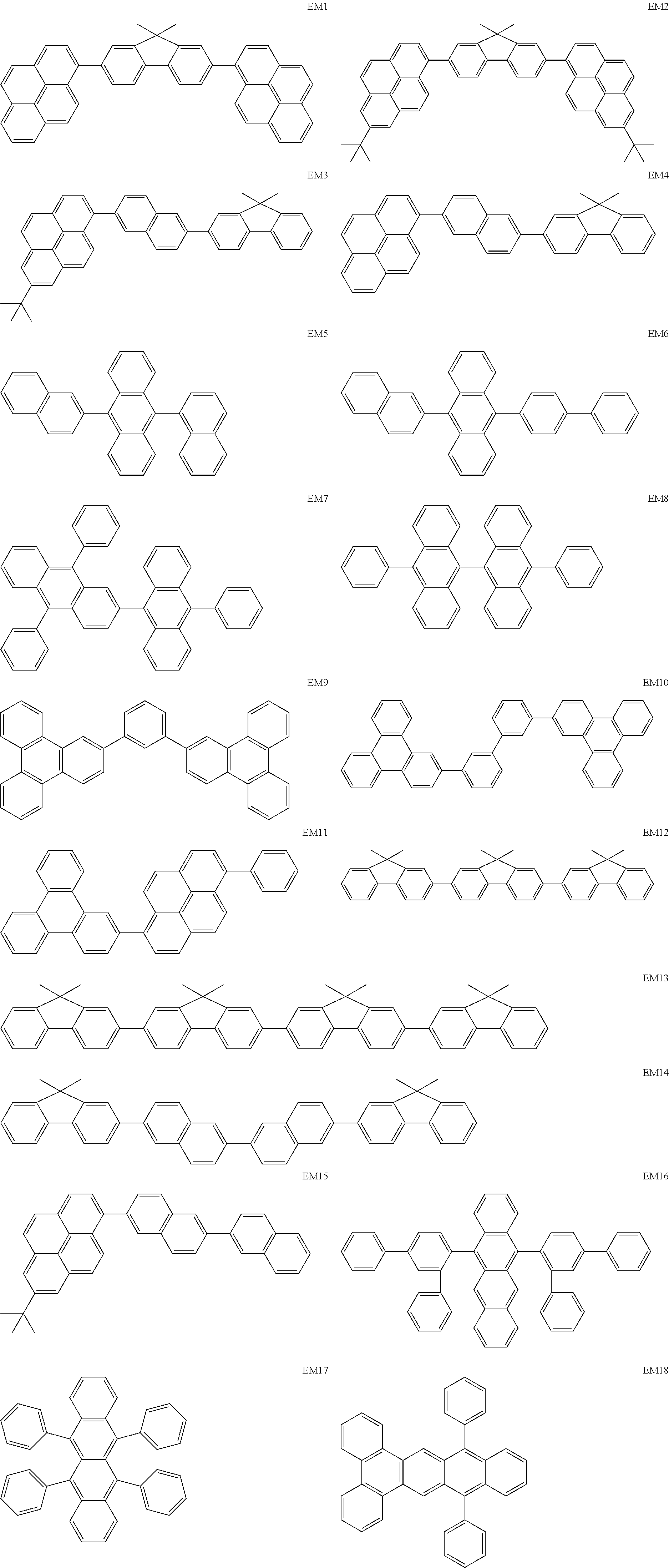

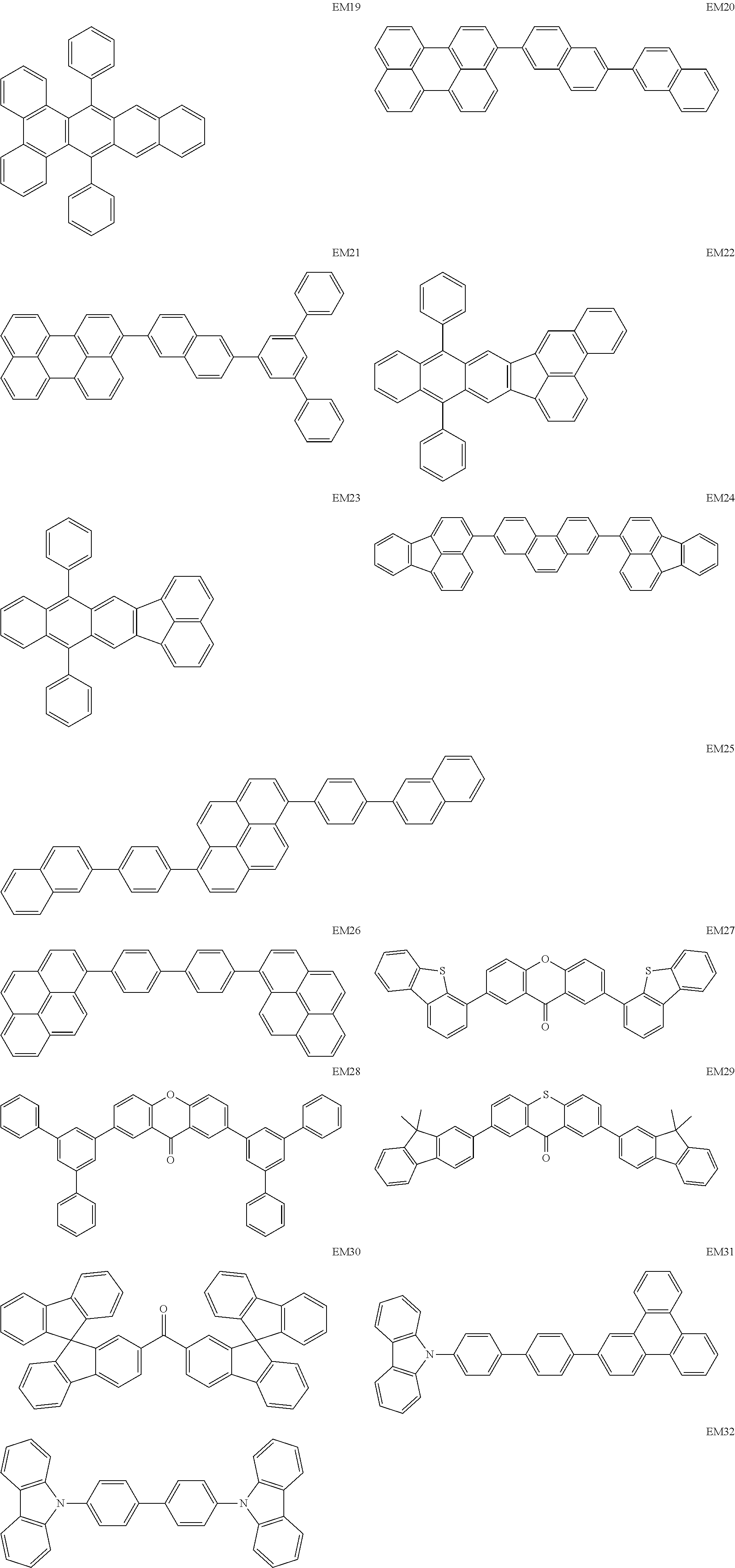

When the host material is a hydrocarbon compound, the effect of improving efficiency can be significant because the light emitting material can easily trap electrons and holes. Hydrocarbon compounds are compounds made up of only carbon and hydrogen, and are EM1 to EM26 among the illustrated compounds. Host materials can be the ones that do not have carbon-heteroatom bonds in single bonds connecting aryl group units in their structure from the viewpoint of stability.

Electron transport materials can be freely selected from those that can transport electrons injected from the cathode to the light emitting layer, and are selected in consideration of, for example, the balance with the hole mobility of the hole transport material. Materials with electronic transport capabilities include oxadiazole derivatives, oxazole derivatives, pyrazine derivatives, triazole derivatives, triazine derivatives, quinoline derivatives, quinoxaline derivatives, phenanthroline derivatives, organic aluminum complexes, and fused ring compounds (such as fluorene derivatives, naphthalene derivatives, chrysene derivatives, and anthracene derivatives). Furthermore, the electron transport materials are also suitably used in hole blocking layers. Hereinafter, specific examples of compounds used as electron transport materials will be described; however, of course, the electron transport materials are not limited thereto.

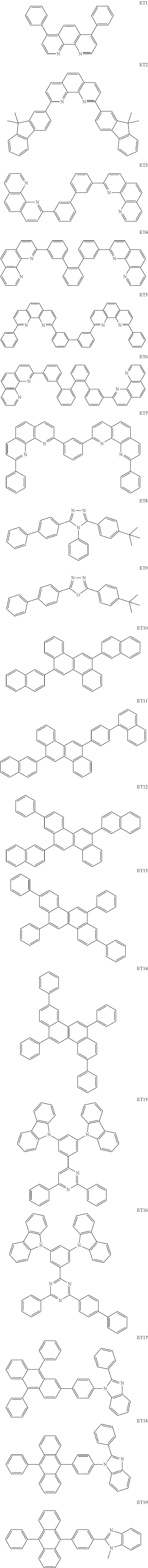

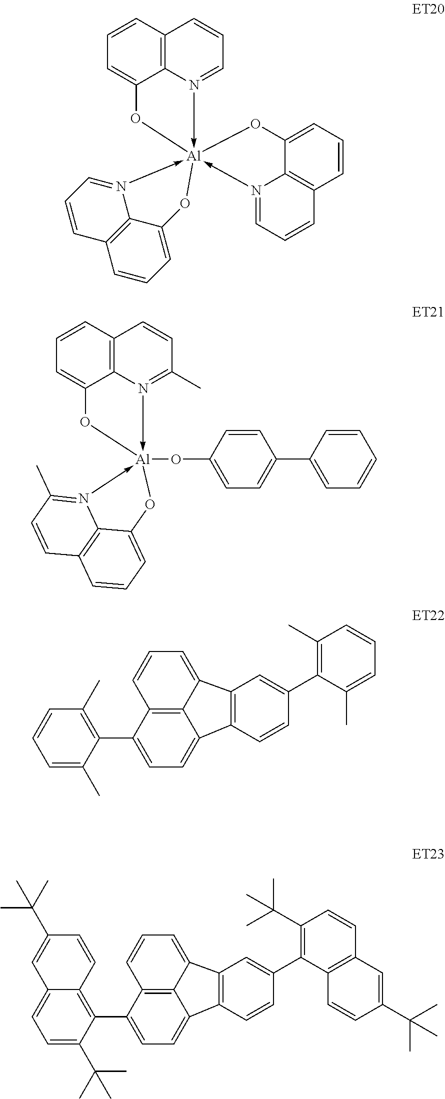

Electron injection materials can be freely selected from those that can easily inject electrons from the cathode, and are selected in consideration of, for example, the balance with hole injection properties. Organic compounds also include n-type dopants and reducing dopants. Examples of the n-type dopants and reducing dopants include compounds including an alkali metal such as a lithium fluoride, a lithium complex such as lithium quinolinolate, a benzimidazolylidene derivative, an imidazolylidene derivative, a fulvalene derivative, and an acridine derivative. The electron injection materials can also be used in conjunction with the electron transport materials.

### Uses of Organic Light Emitting Apparatus

The organic light emitting apparatus of the present embodiment may be used as a constituent member of a display apparatus or a constituent member of an illumination apparatus. Other than those, there are uses, such as an exposure light source of an electrophotographic image forming apparatus and a light emitting apparatus including color filters for a backlight or white light source of a liquid crystal display apparatus.

A display apparatus may be an image information processing apparatus. The image information processing apparatus includes an image input unit that enters image information from an area CCD, a linear CCD, a memory card, or the like, and an information processing unit that processes input information. The image information processing apparatus displays the input image on a display portion. The display apparatus may include the organic light emitting apparatus according to the present embodiment and transistors connected to the organic light emitting apparatus.

A display portion of an image capturing apparatus or ink-jet printer may have a touch panel function. A drive system of the touch panel function may be an infrared radiation method, a capacitance method, a resistive film method, or an electromagnetic induction method and is not limited. A display apparatus may be used as a display portion of a multifunction printer.

Next, a display apparatus according to the present embodiment will be described with reference to the attached drawings.

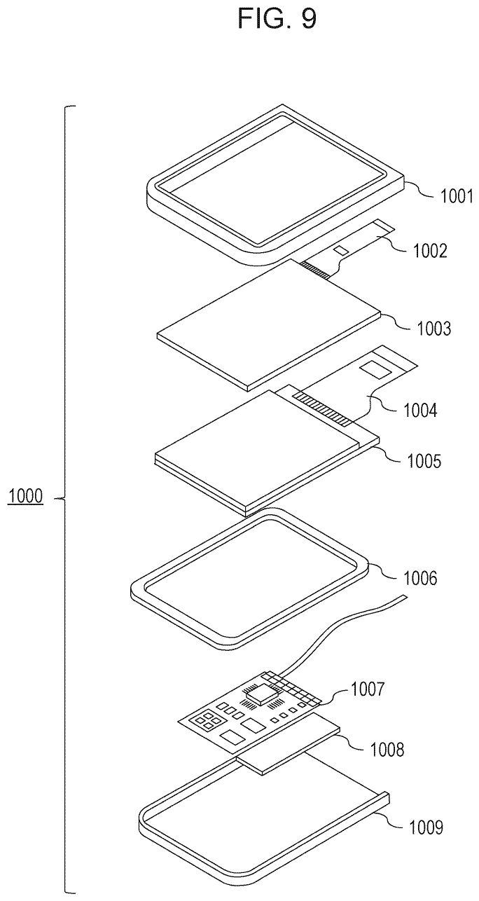

FIG. 9 is a schematic exploded view that shows an example of the display apparatus according to the present embodiment. The display apparatus 1000 includes a touch panel 1003, a display panel 1005, a frame 1006, a circuit board 1007, and a battery 1008 between a top cover 1001 and a bottom cover 1009.

A flexible printed circuit (FPC) 1002 is connected to the touch panel 1003. A flexible printed circuit (FPC) 1004 is connected to the display panel 1005. Transistors are printed on the circuit board 1007. The battery 1008 does not need to be provided when the display apparatus is not a mobile device, or may be provided at another position even when the display apparatus is a mobile device.

The display apparatus according to the present embodiment may include red, green, and blue color filters. The red, green, and blue color filters may be arranged in a delta array.

The display apparatus according to the present embodiment is used in a display portion of a mobile terminal. In this case, the display portion may have a display function and an operating function. Examples of the mobile terminal include a cellular phone such as a smartphone, a tablet, and a head mounted display.

The display apparatus according to the present embodiment is used in a display portion of an image capturing apparatus including an optical unit having a plurality of lenses and an image sensor that receives light passing through the optical unit. The image capturing apparatus may include a display portion that displays information acquired by the image sensor. The display portion may be a display portion exposed to the outside of the image capturing apparatus or may be a display portion disposed in a viewfinder. The image capturing apparatus may be a digital camera or a digital camcorder.

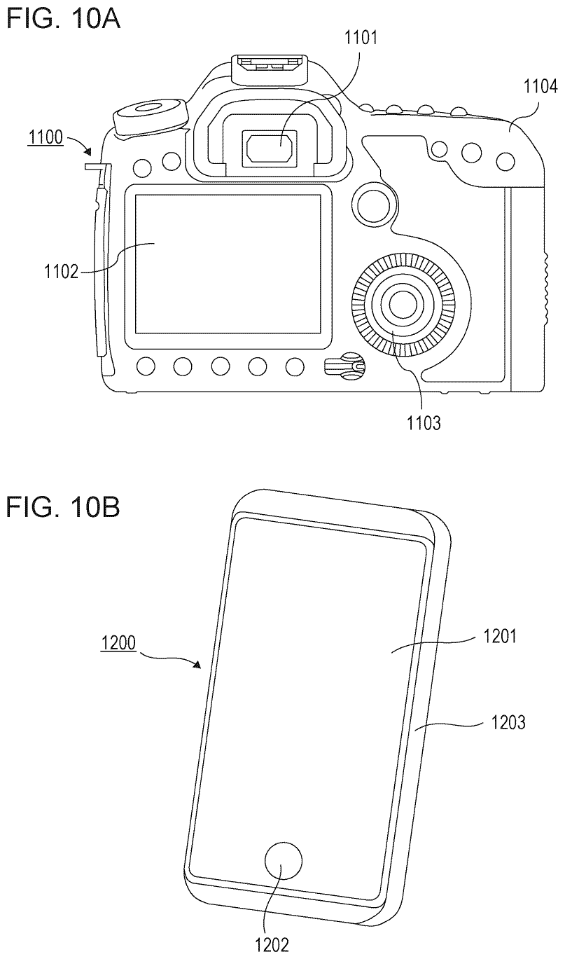

FIG. 10A is a schematic view that shows an example of the image capturing apparatus according to the present embodiment. The image capturing apparatus 1100 includes a viewfinder 1101, a back display 1102, an operating portion 1103, and a housing 1104. The viewfinder 1101 includes the display apparatus according to the present embodiment. In this case, the display apparatus may display not only an image to be captured but also environmental information, an image capturing instruction, and the like. The environmental information may include the intensity of external light, the direction of external light, the moving speed of a subject, a possibility that a subject is shielded by a shielding material, or the like.

Since suitable timing for image capturing is a slight amount of time, information is desirably displayed as early as possible. Therefore, the display apparatus that employs the organic light emitting apparatus according to the present embodiment can be used. This is because the organic light emitting apparatus has a higher response speed. The display apparatus using the organic light emitting apparatus can be more suitably used than these apparatuses and a liquid crystal display apparatus of which a higher display speed is desired.

The image capturing apparatus 1100 includes an optical unit (not shown). The optical unit has a plurality of lenses and forms an image on the image sensor accommodated in the housing 1104. The plurality of lenses is capable of adjusting a focal point by adjusting the relative positions of the lenses. This operation can be automatically performed. The image capturing apparatus may be called a photoelectric conversion apparatus. The photoelectric conversion apparatus can include not a method of sequentially capturing an image but a method of detecting a difference from a previous image, a method of extracting an image from an image being constantly recorded, or the like, as a method of capturing an image.

FIG. 10B is a schematic view that shows an example of an electronic device according to the present embodiment. The electronic device 1200 includes a display portion 1201, an operating portion 1202, and a housing 1203. The housing 1203 may contain a circuit, a printed circuit board having the circuit, a battery, and a communication unit. The operating portion 1202 may be a button or may be a touch panel-type response unit. The operating portion 1202 may be a biometric authentication unit that identifies a fingerprint to, for example, release a lock. The electronic device 1200 including the communication unit may be regarded as a communication device. The electronic device 1200 may further have a camera function by including a lens and an image sensor. An image captured by the camera function is shown on the display portion 1201. The electronic device 1200 may be a smartphone, a notebook computer, or the like.

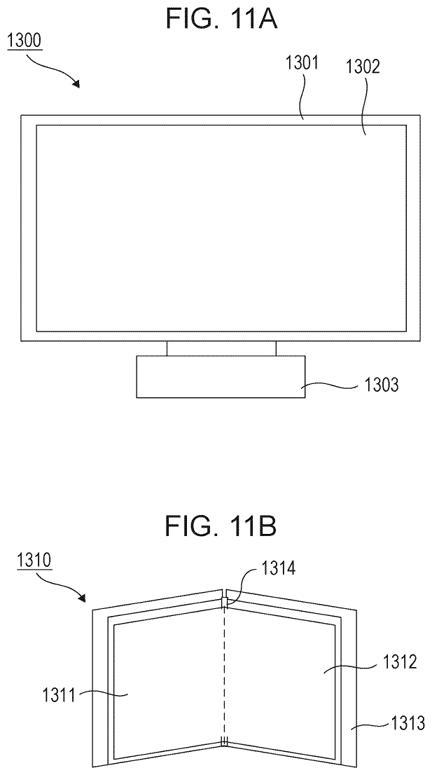

FIGS. 11A and 11B are schematic views that show examples of the display apparatus according to the present embodiment. FIG. 11A is a display apparatus, such as a television monitor or a PC monitor. The display apparatus 1300 includes a frame 1301 and a display portion 1302. The organic light emitting apparatus according to the present embodiment is used as the display portion 1302. The display apparatus 1300 includes a base 1303 that supports the frame 1301 and the display portion 1302. The base 1303 is not limited to the mode of FIG. 11A. The bottom side of the frame 1301 may serve as a base. The frame 1301 and the display portion 1302 may be curved. The radius of curvature may be greater than or equal to 5000 mm and less than or equal to 6000 mm.

FIG. 11B is a schematic view that shows another example of the display apparatus according to the present embodiment. The display apparatus 1310 of FIG. 11B is configured to be foldable, and is a so-called foldable display apparatus. The display apparatus 1310 includes a first display portion 1311, a second display portion 1312, a housing 1313, and a folding point 1314. The first display portion 1311 and the second display portion 1312 each may include the organic light emitting apparatus according to the present embodiment. The first display portion 1311 and the second display portion 1312 may make up a seamless one-sheet display apparatus. The first display portion 1311 and the second display portion 1312 may be separated at the folding point 1314. The first display portion 1311 and the second display portion 1312 may respectively display different images or the first and second display portions 1311, 1312 may display one image.

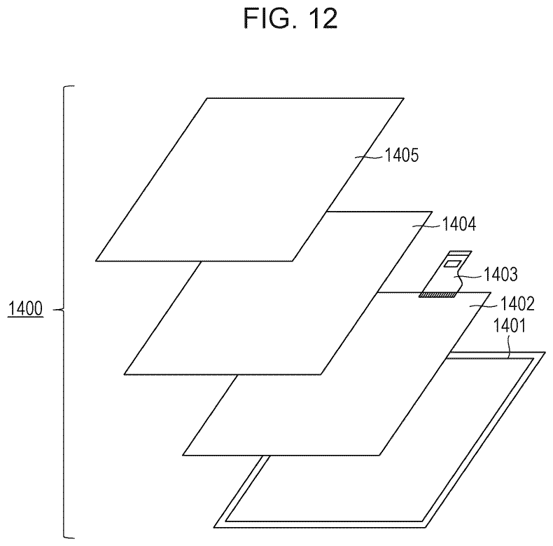

FIG. 12 is a schematic exploded view that shows an example of an illumination apparatus according to the present embodiment. The illumination apparatus 1400 includes a housing 1401, a light source 1402, a circuit board 1403, an optical filter 1404, and a light diffusion unit 1405. The light source 1402 includes the organic light emitting apparatus according to the present embodiment. The optical filter 1404 may be a filter that improves the color rendering property of the light source. The light diffusion unit 1405 is capable of effectively diffusing light from the light source 1402 for illumination or the like to bring light to a wide range. The optical filter 1404 and the light diffusion unit 1405 may be provided on the light emission side of illumination. Where necessary, a cover may be provided at the outermost part.

The illumination apparatus 1400 is an apparatus that illuminates, for example, a room. The illumination apparatus 1400 may produce light in any one of white color, daylight color, and other colors from blue to red. The illumination apparatus 1400 may include a light modulating circuit that modulates light of any of those colors. The illumination apparatus 1400 includes the organic light emitting apparatus according to the present embodiment and a power supply circuit connected to the organic light emitting apparatus. The power supply circuit is a circuit that converts alternating-current voltage to direct-current voltage. White has a color temperature of 4200K, and daylight color has a color temperature of 5000K. The illumination apparatus 1400 may include a color filter.

The illumination apparatus 1400 according to the present embodiment may include a heat radiation portion. The heat radiation portion is to emit heat inside the apparatus to the outside of the apparatus and may be made of a metal having a high specific heat, liquid silicone, or the like.

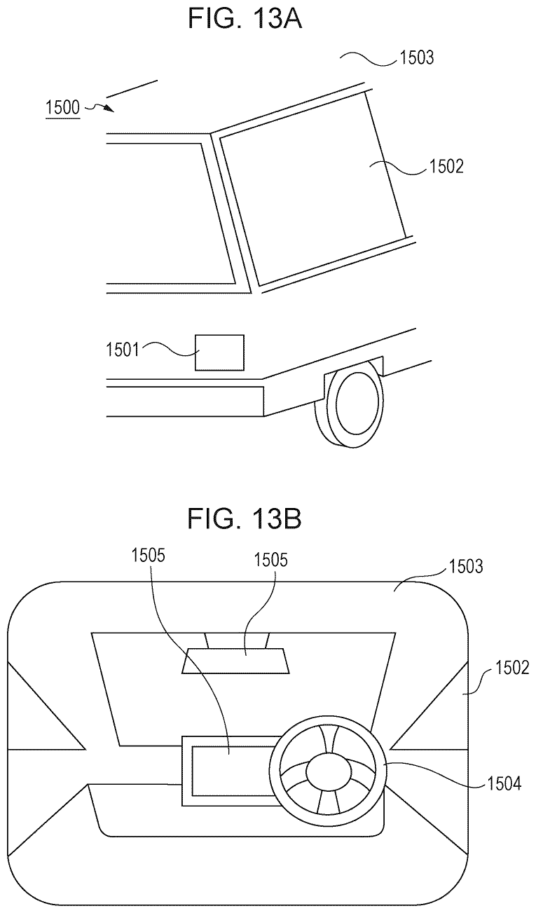

FIG. 13A is a schematic view of an automobile that is an example of a moving object according to the present embodiment. As shown in FIG. 13A, the automobile 1500 includes a tail lamp 1501 that is an example of a lamp. The automobile 1500 includes the tail lamp 1501 and may be configured to, when brake operation or the like is performed, turn on the tail lamp 1501.

The tail lamp 1501 includes the organic light emitting apparatus according to the present embodiment. The tail lamp 1501 may include a protective member that protects the organic light emitting apparatus. The protective member may be made of any material as long as the protective member has a high strength to a certain extent and can be made of polycarbonate or the like. A furan dicarboxylic acid derivative, an acrylonitrile derivative, or the like may be mixed with polycarbonate.

The automobile 1500 may include a body 1503 and windows 1502 fixed to the body 1503. The windows 1502 other than windows for viewing the front and rear of the automobile 1500 each may be a transparent display. The transparent display includes the organic light emitting apparatus according to the present embodiment. In this case, the constituent materials of the electrodes and the like of each organic light emitting apparatus are made up of transparent members.

As shown in FIG. 13B, the automobile 1500 includes a steering wheel 1504 used to control the moving direction of the moving object, a display portion 1505 mounted on the vehicle body 1503 that shows a map, the position of the moving object, the direction to turn, and the like. The display portion 1505 includes the organic light emitting apparatus according to the present embodiment.

Here, an example in which the moving object is an automobile has been described. Alternatively, the moving object according to the present embodiment may also be a ship, an airplane, a drone, or the like. The moving object includes a body and a lamp and display portion provided on the body. The lamp produces light for informing a position of the body. Any of the lamp and the display portion includes the organic light emitting apparatus according to the present embodiment.

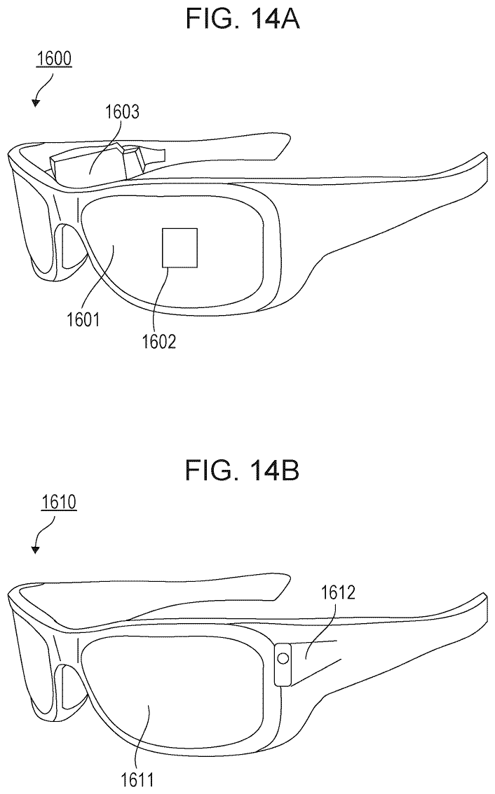

Application examples of the display apparatus of each of the above-described embodiments will be described with reference to FIGS. 14A and 14B. The display apparatus is applicable to a wearable system as a wearable device, such as smartglasses, an HMD, and a smart contact lens. An image capturing and display apparatus used in such application examples includes an image capturing apparatus capable of performing photoelectric conversion of visible light and a display apparatus capable of producing visible light.

FIG. 14A is a schematic view of glasses 1600 (smartglasses) according to one application example. An image capturing apparatus 1602, such as a CMOS sensor and an SPAD, is provided on the front side of a lens 1601 of the glasses 1600. The display apparatus of any one of the above-described embodiments is provided on the back side of the lens 1601.

The glasses 1600 further include a controller 1603. The controller 1603 functions as a power supply to supply electric power to the image capturing apparatus 1602 and the display apparatus according to any one of the embodiments. The controller 1603 controls the operations of the image capturing apparatus 1602 and the display apparatus. An optical system for condensing light to the image capturing apparatus 1602 is formed in the lens 1601.

FIG. 14B illustrates glasses 1610 (smartglasses) according to one application example. The glasses 1610 include a controller 1612. An image capturing apparatus corresponding to the image capturing apparatus 1602 in FIG. 14A and a display apparatus are installed in the controller 1612. The image capturing apparatus in the controller 1612 and an optical system for projecting light produced from the display apparatus are formed in a lens 1611, and an image is projected onto the lens 1611. The controller 1612 functions as a power supply to supply electric power to the image capturing apparatus and the display apparatus and also controls the operations of the image capturing apparatus and the display apparatus. The controller 1612 may include a gaze detection unit that detects the gaze of a wearer. Gaze detection may use infrared light. An infrared emitting unit emits infrared light to the eye of a user gazing at a display image. Infrared light emitted and reflected from the eye is detected by an image capturing unit including a light receiving element. Thus, a captured image of the eye is obtained. A reducer that reduces light from the infrared emitting unit to the display portion in a plan view is provided, so a decrease in image quality is reduced.

The gaze of the user toward the display image is detected from the captured image of the eye, obtained through image capturing with infrared light. A selected known technique may be applied to gaze detection using a captured image of eye. In an example, a gaze detection method based on a Purkinje image caused by reflection of irradiation light on a cornea may be used. More specifically, a gaze detection process based on a pupil-cornea reflection method is performed. A gaze vector indicating the orientation (rotational angle) of the eye is calculated based on the pupil image contained in a captured image of the eye and a Purkinje image by using the pupil-cornea reflection method. Thus, the gaze of a user is detected.

The display apparatus according to the present embodiment may include an image capturing apparatus having a light receiving element and may control a display image of the display apparatus based on gaze information of a user from the image capturing apparatus. Specifically, the display apparatus determines a first field of view region where the user gazes and a second field of view region other than the first field of view region based on gaze information. A first field of view region and a second field of view region may be determined by the controller of the display apparatus or may receive a first field of view region and a second field of view region determined by an external controller. In a display region of the display apparatus, the display resolution of the first field of view region may be controlled so as to be higher than the display resolution of the second field of view region. In other words, the resolution of the second field of view region may be made lower than the resolution of the first field of view region.

A display region includes a first display region and a second display region different from the first display region, and a region having a higher priority is determined based on gaze information from among the first display region and the second display region. A first field of view region and a second field of view region may be determined by the controller of the display apparatus or may receive a first field of view region and a second field of view region determined by an external controller. The resolution of a region having a higher priority may be controlled so as to be higher than the resolution of a region other than the region having a higher priority. In other words, the resolution of a region having a relatively lower priority may be decreased.

AI may be used to determine a first field of view region or a region having a higher priority. AI may be a model configured to estimate an angle of gaze and a distance to an object ahead of the gaze from an image of an eye by using the images of the eye and corresponding directions in which the eye of the image is actually viewing as training data. The display apparatus, or the image capturing apparatus, or an external apparatus may include an AI program. When the external apparatus includes an AI program, the information of the first field of view region or the region having a higher priority is transmitted to the display apparatus via communication.

When display control is performed based on gaze detection, the display apparatus is suitably applicable to smartglasses further including an image capturing apparatus that captures an outside image. The smartglasses are capable of displaying captured outside information in real time.

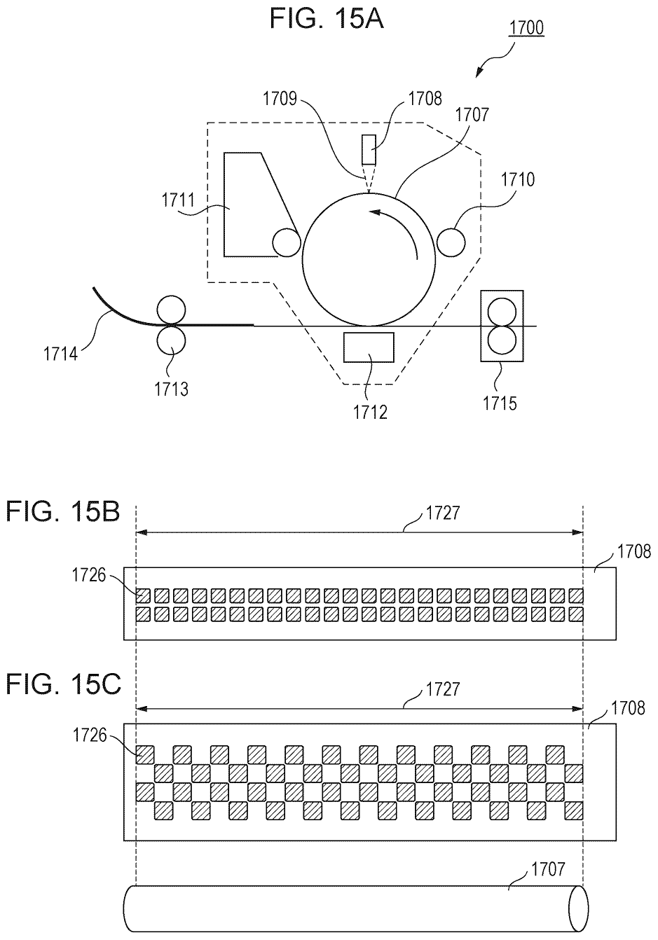

FIG. 15A is a schematic view that shows an example of an image forming apparatus according to the present embodiment. The image forming apparatus 1700 is an electrophotographic image forming apparatus and includes a photoconductor 1707, an exposure light source 1708, a charging portion 1710, a developing portion 1711, a transfer unit 1712, conveyance rollers 1713, and a fuser 1715. Light 1709 is applied from the exposure light source 1708, and an electrostatic latent image is formed on the surface of the photoconductor 1707. The exposure light source 1708 includes the organic light emitting apparatus according to the present embodiment. The developing portion 1711 has toner and the like. The charging portion 1710 electrostatically charges the photoconductor 1707.

The transfer unit 1712 transfers the developed image to a print medium 1714. The conveyance rollers 1713 convey the print medium 1714. The print medium 1714 is, for example, paper. The fuser 1715 fuses the image formed on the print medium 1714.

FIGS. 15B and 15C are views that show the exposure light source 1708, and are schematic views that show a state where a plurality of light emitting portions 1726 is arranged on a long substrate. The arrow 1727 indicates a direction parallel to the axis of the photoconductor 1707 and represents a column direction in which the organic light emitting apparatuses are arranged. This column direction is the same as the direction of the axis around which the photoconductor 1707 rotates. This direction can also be referred to as the major-axis direction of the photoconductor 1707. FIG. 15B shows a mode where the light emitting portions 1726 are arranged along the major-axis direction of the photoconductor 1707. Each of the light emitting portions 1726 includes the organic light emitting apparatus according to the present embodiment.

FIG. 15C is a mode different from FIG. 15B and shows a mode where the light emitting portions 1726 are alternately arranged in the column direction for each of the first and second columns. The light emitting portions 1726 are arranged at different positions in the row direction between the first column and the second column. The first column has a plurality of the light emitting portions 1726 arranged with spaces therebetween. The second column has the light emitting portions 1726 at positions corresponding to the spaces between the light emitting portions 1726 of the first column. In other words, in the row direction as well, a plurality of the light emitting portions 1726 is arranged with spaces therebetween. The arrangement of FIG. 15C can be described as, for example, a state of being arranged in a grid pattern, a state of being arranged in a staggered pattern, or a checkerboard pattern.

As described above, with the use of the organic light emitting apparatus according to the present embodiment, stable display can be achieved even for a long time with good image quality.

According to one aspect of the present disclosure, it is possible to provide a light emitting apparatus that suppresses a decrease in luminous efficiency.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-143434, filed Aug. 23, 2024, which is hereby incorporated by reference herein in its entirety.

What is claimed is:

1. An organic light emitting apparatus comprising:
a substrate having a surface;
a first lower electrode and a second lower electrode arranged adjacent to each other and on the surface of the substrate;
an insulating layer disposed on the substrate, the insulating layer separating the first lower electrode and the second lower electrode, the insulating layer having a first opening portion on the first lower electrode, and the insulating layer having a second opening portion on the second lower electrode;
a first lower charge transport layer disposed in the first opening portion;
a first light emitting layer disposed on the first lower charge transport layer;
a second lower charge transport layer disposed in the second opening portion;
a second light emitting layer disposed on the second lower charge transport layer; and
an upper charge transport layer disposed on the first light emitting layer and the second light emitting layer, wherein
in a plan view to the surface, at least one of the first lower charge transport layer, the second lower charge transport layer, the first light emitting layer, or the second light emitting layer is overlapped with a flat portion between the first opening portion and the second opening portion of the insulating layer,
in the plan view to the surface, an area of the first light emitting layer is larger than an area of the first lower charge transport layer,
in the plan view to the surface, an area of the second light emitting layer is larger than an area of the second lower charge transport layer, and
the following expression (1) is satisfied,
$${H}_{H 1} > {H}_{EM 1} > {E}_{H 3} \qquad ( 1 )$$
where H_{H1} denotes a hole mobility of the first lower charge transport layer,
H_{EM1} denotes a hole mobility of the first light emitting layer, and
E_{H3} denotes an electron mobility of the upper charge transport layer.

2. The organic light emitting apparatus according to claim 1, wherein the upper charge transport layer is disposed on the first light emitting layer, the second light emitting layer, and the insulating layer.

3. The organic light emitting apparatus according to claim 1, wherein the first lower charge transport layer is contained in the first light emitting layer in the plan view.

4. The organic light emitting apparatus according to claim 1, wherein the second lower charge transport layer is contained in the second light emitting layer in the plan view.

5. The organic light emitting apparatus according to claim 1, wherein the first opening portion is contained in the first lower charge transport layer in the plan view.

6. The organic light emitting apparatus according to claim 1, wherein the first opening portion is contained in the first light emitting layer in the plan view.

7. The organic light emitting apparatus according to claim 1, wherein the second opening portion is contained in the second lower charge transport layer in the plan view.

8. The organic light emitting apparatus according to claim 1, wherein the second opening portion is contained in the second light emitting layer in the plan view.

9. The organic light emitting apparatus according to claim 1, wherein the upper charge transport layer is a common layer disposed continuously on the first light emitting layer and the second light emitting layer.

10. The organic light emitting apparatus according to claim 1, wherein the following expression (2) is satisfied,
$${H}_{H 2} > {H}_{EM 2} > {E}_{H 3} \qquad ( 2 )$$
where H_{H2} denotes a hole mobility of the second lower charge transport layer,
H_{EM2} denotes a hole mobility of the second light emitting layer, and
E_{H3} denotes an electron mobility of the upper charge transport layer.

11. The organic light emitting apparatus according to claim 1, wherein the first lower charge transport layer and the first light emitting layer are overlapped with a flat portion between the first opening portion and the second opening portion of the insulating layer in the plan view.

12. The organic light emitting apparatus according to claim 1, wherein the second lower charge transport layer and the second light emitting layer are overlapped with the flat portion between the first opening portion and the second opening portion of the insulating layer in the plan view.

13. The organic light emitting apparatus according to claim 1, wherein the insulating layer has an inclined portion rising from an opening portion and the flat portion continuous with the inclined portion.

14. The organic light emitting apparatus according to claim 1, wherein the first light emitting layer and the second light emitting layer have overlapping portions in the plan view.

15. The organic light emitting apparatus according to claim 1, wherein the first lower charge transport layer and the second lower charge transport layer have overlapping portions in the plan view.

16. The organic light emitting apparatus according to claim 1, further comprising a reflective layer and an optical adjustment layer from the substrate side between the substrate and both the first lower electrode and the second lower electrode, wherein a thickness of the optical adjustment layer under the first lower electrode and a thickness of the optical adjustment layer under the second lower electrode are different from each other.

17. The organic light emitting apparatus according to claim 17, wherein the insulating layer has the flat portion positioned along a perimeter of an opening portion, an inclined portion rising from the flat portion, and a second flat portion continuous with the inclined portion.

18. The organic light emitting apparatus according to claim 18, wherein at least one of the first lower charge transport layer, the second lower charge transport layer, the first light emitting layer, or the second light emitting layer is overlapped with the second flat portion in the plan view.

19. A display apparatus comprising:
a display portion including the organic light emitting apparatus according to claim 1; and
a housing in which the display portion is provided.

20. A photoelectric conversion apparatus comprising:
an image sensor configured to receive light; and
a display portion configured to display an image captured by the image sensor, wherein
the display portion includes the organic light emitting apparatus according to claim 1.

21. An electronic device comprising:
a display portion including the organic light emitting apparatus according to claim 1;
a housing in which the display portion is provided; and
a communication unit provided in the housing and configured to communicate with an external source.

22. A wearable device comprising:
a display portion including the organic light emitting apparatus according to claim 1;
an optical system configured to condense light from the display portion; and
a controller configured to control display of the display portion.

23. An illumination apparatus comprising:
a light source including the organic light emitting apparatus according to claim 1; and
a housing in which the light source is provided.

24. A moving object comprising:
a display portion including the organic light emitting apparatus according to claim 1; and
a body on which the display portion is provided.

25. An image forming apparatus comprising:
a photoconductor, and
an exposure light source configured to expose the photoconductor to light, wherein the exposure light source includes the organic light emitting apparatus according to claim 1.
